(19) United States
(12) Patent Application Publication
(10) Pub. No.: US 2011/0217824 A1
(43) Pub. Date: Sep. 8, 2011

(54) ELECTRODE STRUCTURE, METHOD OF FABRICATING THE SAME, AND SEMICONDUCTOR DEVICE

(75) Inventor: Masahiko OHUCHI, Tokyo (JP)

(73) Assignee: ELPIDA MEMORY, INC., Tokyo (JP)

(21) Appl. No.: 13/037,811

(22) Filed: Mar. 1, 2011

(30) Foreign Application Priority Data
Mar. 3, 2010 (JP) 2010-047069

(51) Int. Cl. H01L 21/02

(52) U.S. Cl. 438/382; 257/E21.004

(57) ABSTRACT

A method for fabricating a semiconductor device includes the following processes. A first groove is formed in a first insulating film. A first conductive film is formed on inner surfaces of the first groove. A second groove is formed in the first insulating film to remove a part of the first conductive film. The second groove intersects the first groove.

### BACKGROUND OF THE INVENTION

1. Field of the Invention

The present invention relates to an electrode structure, a method of fabricating the same, and a semiconductor device including the electrode structure.

Priority is claimed on Japanese Patent Application No. 2010-047069, Mar. 3, 2010, the content of which is incorporated herein by reference.

2. Description of the Related Art

Japanese Unexamined Patent Application, First Publication, No. JP-A-2006-019688 discloses that a phase-change memory (hereinafter, PRAM) using a variation in resistance of a phase change layer has been developed as a semiconductor memory device.

The PRAM functions as a memory element in the following manner. The state of a variable resistance material layer is transferred from an amorphous state to a crystal state or from the crystalline state to the amorphous state by applying current to an electrode contacting the variable resistance. The variable resistance material layer in the amorphous state has a high resistivity. On the other hand, the variable resistance material layer in the crystalline state has a low resistivity.

The operation characteristics of the PRAM may be improved by reducing a contact area between the variable resistance material layer and the electrode to shrink a phase-change region. In other words, the operation characteristics of the PRAM may be improved by shrinking a size of the electrode. To this end, downscaling of the electrode is required.

Japanese Unexamined Patent Application, First Publication, No. JP-A-2006-019688 discloses a method of forming an electrode which is downscalable. The method of forming the electrode includes forming a contact hole in an insulating film, forming a spacer on a sidewall of the contact hole to reduce a diameter of the contact hole, and filling the contact hole having the spacer with a conductive film.

In addition, Japanese Unexamined Patent Application, Second Publication, No. JP-A-2003-229497 and Japanese Unexamined Patent Application, Third Publication, No. JP-A-2005-150333 disclose the following processes. A method of forming contact holes includes overlapping a first resist mask and a second resist mask with each other on an insulating layer and etching the insulating layer through the first and second resist masks to form a fine contact hole in the insulating layer. Here, the first resist mask has a plurality of first grooves extending in a first direction. The second resist mask has a plurality of second grooves extending in a second direction different from the first direction and intersecting with the first grooves.

### SUMMARY

In one embodiment, a method for fabricating a semiconductor device may include, but is not limited to, the following processes. A first groove is formed in a first insulating film. A first electrode film is formed on inner surfaces of the first groove. A second groove is formed in the first insulating film to remove a part of the first electrode film. The second groove intersects the first groove.

In another embodiment, a method for fabricating a semiconductor device may include, but is not limited to, the following processes. A first groove is formed in a first insulating film. A first conductive film is formed on inner surfaces of the first groove. Second and third grooves are formed in the first insulating film to define the first conductive film into an electrode. The second and third grooves intersect the first groove.

In still another embodiment, a method for fabricating a semiconductor device may include, but is not limited to, the following processes. A first insulating film is formed over a semiconductor substrate. A first groove is formed in the first insulating film, the first groove extending in a first direction. A first conductive film is formed on a bottom surface and side surfaces of the first groove. A second groove is formed in the first insulating film to remove a part of the first conductive film and to define an electrode. The second groove extends in a second direction. The second groove intersects the first groove.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a fragmentary plan view illustrating a structure including an electrode structure in accordance with one embodiment of the present invention;

FIG. 1B is a fragmentary cross sectional elevation view, taken along an A-A line of FIG. 1A, illustrating a structure including an electrode structure in accordance with one embodiment of the present invention;

FIG. 1C is a fragmentary cross sectional elevation view, taken along a B-B line of FIG. 1A, illustrating a structure including an electrode structure in accordance with one embodiment of the present invention;

FIG. 1D is a fragmentary cross sectional elevation view, taken along a C-C line of FIG. 1A, illustrating a structure including an electrode structure in accordance with one embodiment of the present invention;

FIG. 2A is a fragmentary plan view illustrating a structure including an electrode structure in a step involved in a method of forming the structure of FIGS. 1A to 1D in accordance with one embodiment of the present invention;

FIG. 2B is a fragmentary cross sectional elevation view, taken along an A-A line of FIG. 2A, illustrating a structure including an electrode structure in a step involved in a method of forming the structure of FIGS. 1A to 1D in accordance with one embodiment of the present invention;

FIG. 2C is a fragmentary cross sectional elevation view, taken along a B-B line of FIG. 2A, illustrating a structure including an electrode structure in a step involved in a method of forming the structure of FIGS. 1A to 1D in accordance with one embodiment of the present invention;

FIG. 3A is a fragmentary plan view illustrating a structure including an electrode structure in a step, subsequent to the step of FIGS. 2A to 2C, involved in a method of forming the structure of FIGS. 1A to 1D in accordance with one embodiment of the present invention;

FIG. 3B is a fragmentary cross sectional elevation view, taken along an A-A line of FIG. 3A, illustrating a structure including an electrode structure in a step, subsequent to the step of FIGS. 2A to 2C, involved in a method of forming the structure of FIGS. 1A to 1D in accordance with one embodiment of the present invention;

FIG. 3C is a fragmentary cross sectional elevation view, taken along a B-B line of FIG. 3A, illustrating a structure including an electrode structure in a step, subsequent to the step of FIGS. 2A to 2C, involved in a method of forming the structure of FIGS. 1A to 1D in accordance with one embodiment of the present invention;

FIG. 4A is a fragmentary plan view illustrating a structure including an electrode structure in a step, subsequent to the step of FIGS. 3A to 3C, involved in a method of forming the structure of FIGS. 1A to 1D in accordance with one embodiment of the present invention;

FIG. 4B is a fragmentary cross sectional elevation view, taken along an A-A line of FIG. 4A, illustrating a structure including an electrode structure in a step, subsequent to the step of FIGS. 3A to 3C, involved in a method of forming the structure of FIGS. 1A to 1D in accordance with one embodiment of the present invention;

FIG. 4C is a fragmentary cross sectional elevation view, taken along a B-B line of FIG. 4A, illustrating a structure including an electrode structure in a step, subsequent to the step of FIGS. 3A to 3C, involved in a method of forming the structure of FIGS. 1A to 1D in accordance with one embodiment of the present invention;

FIG. 5A is a fragmentary plan view illustrating a structure including an electrode structure in a step, subsequent to the step of FIGS. 4A to 4C, involved in a method of forming the structure of FIGS. 1A to 1D in accordance with one embodiment of the present invention;

FIG. 5B is a fragmentary cross sectional elevation view, taken along an A-A line of FIG. 5A, illustrating a structure including an electrode structure in a step, subsequent to the step of FIGS. 4A to 4C, involved in a method of forming the structure of FIGS. 1A to 1D in accordance with one embodiment of the present invention;

FIG. 5C is a fragmentary cross sectional elevation view, taken along a B-B line of FIG. 5A, illustrating a structure including an electrode structure in a step, subsequent to the step of FIGS. 4A to 4C, involved in a method of forming the structure of FIGS. 1A to 1D in accordance with one embodiment of the present invention;

FIG. 6A is a fragmentary plan view illustrating a structure including an electrode structure in a step, subsequent to the step of FIGS. 5A to 5C, involved in a method of forming the structure of FIGS. 1A to 1D in accordance with one embodiment of the present invention;

FIG. 6B is a fragmentary cross sectional elevation view, taken along an A-A line of FIG. 6A, illustrating a structure including an electrode structure in a step, subsequent to the step of FIGS. 5A to 5C, involved in a method of forming the structure of FIGS. 1A to 1D in accordance with one embodiment of the present invention;

FIG. 6C is a fragmentary cross sectional elevation view, taken along a B-B line of FIG. 6A, illustrating a structure including an electrode structure in a step, subsequent to the step of FIGS. 5A to 5C, involved in a method of forming the structure of FIGS. 1A to 1D in accordance with one embodiment of the present invention;

FIG. 7A is a fragmentary plan view illustrating a structure including an electrode structure in a step, subsequent to the step of FIGS. 6A to 6C, involved in a method of forming the structure of FIGS. 1A to 1D in accordance with one embodiment of the present invention;

FIG. 7B is a fragmentary cross sectional elevation view, taken along an A-A line of FIG. 7A, illustrating a structure including an electrode structure in a step, subsequent to the step of FIGS. 6A to 6C, involved in a method of forming the structure of FIGS. 1A to 1D in accordance with one embodiment of the present invention;

FIG. 7C is a fragmentary cross sectional elevation view, taken along a B-B line of FIG. 7A, illustrating a structure including an electrode structure in a step, subsequent to the step of FIGS. 6A to 6C, involved in a method of forming the structure of FIGS. 1A to 1D in accordance with one embodiment of the present invention;

FIG. 8A is a fragmentary plan view illustrating a structure including an electrode structure in a step, subsequent to the step of FIGS. 7A to 7C, involved in a method of forming the structure of FIGS. 1A to 1D in accordance with one embodiment of the present invention;

FIG. 8B is a fragmentary cross sectional elevation view, taken along an A-A line of FIG. 8A, illustrating a structure including an electrode structure in a step, subsequent to the step of FIGS. 7A to 7C, involved in a method of forming the structure of FIGS. 1A to 1D in accordance with one embodiment of the present invention;

FIG. 8C is a fragmentary cross sectional elevation view, taken along a B-B line of FIG. 8A, illustrating a structure including an electrode structure in a step, subsequent to the step of FIGS. 7A to 7C, involved in a method of forming the structure of FIGS. 1A to 1D in accordance with one embodiment of the present invention;

FIG. 9A is a fragmentary plan view illustrating a structure including an electrode structure in a step, subsequent to the step of FIGS. 8A to 8C, involved in a method of forming the structure of FIGS. 1A to 1D in accordance with one embodiment of the present invention;

FIG. 9B is a fragmentary cross sectional elevation view, taken along an A-A line of FIG. 9A, illustrating a structure including an electrode structure in a step, subsequent to the step of FIGS. 8A to 8C, involved in a method of forming the structure of FIGS. 1A to 1D in accordance with one embodiment of the present invention;

FIG. 9C is a fragmentary cross sectional elevation view, taken along a B-B line of FIG. 9A, illustrating a structure including an electrode structure in a step, subsequent to the step of FIGS. 8A to 8C, involved in a method of forming the structure of FIGS. 1A to 1D in accordance with one embodiment of the present invention;

FIG. 10A is a fragmentary plan view illustrating a structure including an electrode structure in a step, subsequent to the step of FIGS. 9A to 9C, involved in a method of forming the structure of FIGS. 1A to 1D in accordance with one embodiment of the present invention;

FIG. 10B is a fragmentary cross sectional elevation view, taken along an A-A line of FIG. 10A, illustrating a structure including an electrode structure in a step, subsequent to the step of FIGS. 9A to 9C, involved in a method of forming the structure of FIGS. 1A to 1D in accordance with one embodiment of the present invention;

FIG. 10C is a fragmentary cross sectional elevation view, taken along a B-B line of FIG. 10A, illustrating a structure including an electrode structure in a step, subsequent to the step of FIGS. 9A to 9C, involved in a method of forming the structure of FIGS. 1A to 1D in accordance with one embodiment of the present invention;

FIG. 11A is a fragmentary plan view illustrating a structure including an electrode structure in a step, subsequent to the step of FIGS. 10A to 10C, involved in a method of forming the structure of FIGS. 1A to 1D in accordance with one embodiment of the present invention;

FIG. 11B is a fragmentary cross sectional elevation view, taken along an A-A line of FIG. 11A, illustrating a structure including an electrode structure in a step, subsequent to the step of FIGS. 10A to 10C, involved in a method of forming the structure of FIGS. 1A to 1D in accordance with one embodiment of the present invention;

FIG. 11C is a fragmentary cross sectional elevation view, taken along a B-B line of FIG. 11A, illustrating a structure including an electrode structure in a step, subsequent to the step of FIGS. 10A to 10C, involved in a method of forming the structure of FIGS. 1A to 1D in accordance with one embodiment of the present invention;

FIG. 12A is a fragmentary plan view illustrating a structure including an electrode structure in a step, subsequent to the step of FIGS. 11A to 11C, involved in a method of forming the structure of FIGS. 1A to 1D in accordance with one embodiment of the present invention;

FIG. 12B is a fragmentary cross sectional elevation view, taken along an A-A line of FIG. 12A, illustrating a structure including an electrode structure in a step, subsequent to the step of FIGS. 11A to 11C, involved in a method of forming the structure of FIGS. 1A to 1D in accordance with one embodiment of the present invention;

FIG. 12C is a fragmentary cross sectional elevation view, taken along a B-B line of FIG. 12A, illustrating a structure including an electrode structure in a step, subsequent to the step of FIGS. 11A to 11C, involved in a method of forming the structure of FIGS. 1A to 1D in accordance with one embodiment of the present invention;

FIG. 13A is a fragmentary plan view illustrating a structure including an electrode structure in a step, subsequent to the step of FIGS. 12A to 12C, involved in a method of forming the structure of FIGS. 1A to 1D in accordance with one embodiment of the present invention;

FIG. 13B is a fragmentary cross sectional elevation view, taken along an A-A line of FIG. 13A, illustrating a structure including an electrode structure in a step, subsequent to the step of FIGS. 12A to 12C, involved in a method of forming the structure of FIGS. 1A to 1D in accordance with one embodiment of the present invention;

FIG. 13C is a fragmentary cross sectional elevation view, taken along a B-B line of FIG. 13A, illustrating a structure including an electrode structure in a step, subsequent to the step of FIGS. 12A to 12C, involved in a method of forming the structure of FIGS. 1A to 1D in accordance with one embodiment of the present invention;

FIG. 14A is a fragmentary plan view illustrating a structure including an electrode structure in a step involved in another method of forming the structure in accordance with one embodiment of the present invention;

FIG. 14B is a fragmentary cross sectional elevation view, taken along an A-A line of FIG. 14A, illustrating a structure including an electrode structure in a step involved in another method of forming the structure in accordance with one embodiment of the present invention;

FIG. 14C is a fragmentary cross sectional elevation view, taken along a B-B line of FIG. 14A, illustrating a structure including an electrode structure in a step involved in another method of forming the structure in accordance with one embodiment of the present invention;

FIG. 15 is a fragmentary plan view illustrating an active region, a gate electrode, a bit line, a ground interconnection line, an electrode, a third contact plug, and a fourth contact plug formed in a semiconductor device including an electrode structure shown in FIGS. 1A to 1D;

FIG. 16 is a fragmentary cross sectional elevation view, taken along a D-D line of FIG. 15, illustrating a semiconductor device including an electrode structure shown in FIGS. 1A to 1D;

FIG. 17 is a fragmentary cross sectional elevation view, taken along an E-E line of FIG. 15, illustrating a semiconductor device including an electrode structure shown in FIGS. 1A to 1D;

FIG. 18 is a fragmentary cross sectional elevation view, taken along a D-D line of FIG. 15, illustrating a semiconductor device including an electrode structure shown in FIGS. 1A to 1D in a step involved in a method of forming the semiconductor device in accordance with one embodiment of the present invention;

FIG. 19 is a fragmentary cross sectional elevation view, taken along a D-D line of FIG. 15, illustrating a semiconductor device including an electrode structure shown in FIGS. 1A to 1D in a step, subsequent to the step of FIG. 18, involved in a method of forming the semiconductor device in accordance with one embodiment of the present invention;

FIG. 20 is a fragmentary cross sectional elevation view, taken along a D-D line of FIG. 15, illustrating a semiconductor device including an electrode structure shown in FIGS. 1A to 1D in a step, subsequent to the step of FIG. 19, involved in a method of forming the semiconductor device in accordance with one embodiment of the present invention;

FIG. 21 is a fragmentary cross sectional elevation view, taken along a D-D line of FIG. 15, illustrating a semiconductor device including an electrode structure shown in FIGS. 1A to 1D in a step, subsequent to the step of FIG. 20, involved in a method of forming the semiconductor device in accordance with one embodiment of the present invention;

FIG. 22 is a fragmentary cross sectional elevation view, taken along an E-E line of FIG. 15, illustrating a semiconductor device shown in FIG. 21 in accordance with one embodiment of the present invention;

FIG. 23 is a fragmentary cross sectional elevation view, taken along a D-D line of FIG. 15, illustrating a semiconductor device including an electrode structure shown in FIGS. 1A to 1D in a step, subsequent to the step of FIG. 21, involved in a method of forming the semiconductor device in accordance with one embodiment of the present invention;

FIG. 24 is a fragmentary cross sectional elevation view, taken along an E-E line of FIG. 15, illustrating a semiconductor device shown in FIG. 23 in accordance with one embodiment of the present invention;

FIG. 25 is a fragmentary cross sectional elevation view, taken along a D-D line of FIG. 15, illustrating a semiconductor device including an electrode structure shown in FIGS. 1A to 1D in a step, subsequent to the step of FIG. 23, involved in a method of forming the semiconductor device in accordance with one embodiment of the present invention;

FIG. 26 is a fragmentary cross sectional elevation view, taken along an E-E line of FIG. 15, illustrating a semiconductor device shown in FIG. 25 in accordance with one embodiment of the present invention;

FIG. 27A is a fragmentary plan view illustrating a structure including an electrode structure in accordance with another embodiment of the present invention;

FIG. 27B is a fragmentary cross sectional elevation view, taken along an A-A line of FIG. 27A, illustrating a structure including an electrode structure in accordance with another embodiment of the present invention;

FIG. 27C is a fragmentary cross sectional elevation view, taken along a B-B line of FIG. 27A, illustrating a structure including an electrode structure in accordance with another embodiment of the present invention;

FIG. 27D is a fragmentary cross sectional elevation view, taken along a C-C line of FIG. 27A, illustrating a structure including an electrode structure in accordance with another embodiment of the present invention;

FIG. 28 is a fragmentary cross sectional elevation view, taken along an A-A line of FIG. 27A, illustrating a structure including an electrode structure in a step involved in a method of forming the structure of FIGS. 27A to 27D in accordance with another embodiment of the present invention;

FIG. 29 is a fragmentary cross sectional elevation view, taken along an A-A line of FIG. 27A, illustrating a structure including an electrode structure in a step, subsequent to the step of FIG. 28, involved in a method of forming the structure of FIGS. 27A to 27D in accordance with another embodiment of the present invention;

FIG. 30 is a fragmentary cross sectional elevation view, taken along an A-A line of FIG. 27A, illustrating a structure including an electrode structure in a step, subsequent to the step of FIG. 29, involved in a method of forming the structure of FIGS. 27A to 27D in accordance with another embodiment of the present invention; and

FIG. 31 is a fragmentary cross sectional elevation view illustrating a semiconductor device including an electrode structure shown in FIGS. 27A to 27D.

### DETAILED DESCRIPTION OF THE PREFERRED EMBODIMENTS

Before describing the present invention, the related art will be explained in detail, in order to facilitate the understanding of the present invention.

Japanese Unexamined Patent Application, First Publication, No. JP-A-2006-019688 discloses the method of forming the electrode, wherein increase in the thickness of the spacer in a diametrical direction of the contact hole makes it difficult for anisotropic etching process to remove the spacer from a bottom of the contact hole completely. Hence, it is difficult to form a plurality of electrodes having a desired shape with high precision.

In addition, even if the portion of the spacer is completely removed from the bottom of the contact hole, the diameter of the contact hole in which the spacer is provided may be very small in some cases. As a result, very small diameter of the contact hole makes it difficult to fill a metal film in the contact hole with the spacer, the metal film serving as a base material of the electrode. Filling the contact hole is performed without generating a void. Thus, it is difficult to form a plurality of electrodes having a precise shape.

Furthermore, Japanese Unexamined Patent Application, Second Publication, No. JP-A-2003-229497 and Japanese Unexamined Patent Application, Third Publication, No. JP-A-2005-150333 disclose that it is similarly difficult to fill contact holes having fine opening diameters with a metal film serving as a base material of an electrode. Thus, it is difficult to form a plurality of electrodes having a desired shape with high precision.

In particular, when the contact holes have a high aspect ratio, it is difficult to fill the contact hole with the metal film. Here, the aspect ratio refers to a ratio of the depth of a contact hole to the diameter of the contact hole. Thereby, the above-described problem has been serious.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method for fabricating a semiconductor device may include, but is not limited to, the following processes. A first groove is formed in a first insulating film. A first conductive film is formed on inner surfaces of the first groove. A second groove is formed in the first insulating film to remove a part of the first conductive film. The second groove intersects the first groove.

In some cases, the method may further include, but is not limited to, forming a second insulating film on the first conductive film. The second insulating film is in the first groove. Forming the second groove may include removing a part of the first conductive film and a part of the second insulating film.

In some cases, the method may further include, but is not limited to, forming a second conductive film in contact with the first conductive film. The second conductive film is in the first groove.

In some cases, the method may further include, but is not limited to, forming a second insulating film on the first conductive film and the second conductive film. The second insulating film is in the first groove. Forming the second groove may include selectively removing the first conductive film, the second conductive film, and the second insulating film.

In some cases, forming the second groove may include, but is not limited to, forming a mask over the first conductive film and selectively removing the first insulating film and the first conductive film using the mask.

In some cases, forming the second groove may include, but is not limited to, forming a mask over the first conductive film and selectively removing the first insulating film, the first conductive film, and the second conductive film using the mask.

In some cases, forming the second groove may include, but is not limited to, forming a mask over the first conductive film and selectively removing the first insulating film, the first conductive film, the second conductive film, and the second insulating film using the mask.

In some cases, forming the mask may include, but is not limited to, reducing a width of the mask.

In some cases, forming the mask may include, but is not limited to, forming a hard mask over the first conductive film, forming an anti-reflection film over the hard mask, and forming a resist pattern over the anti-reflection film.

In some cases, the method may further include, but is not limited to, forming a variable resistance material layer in contact with a top surface of the first conductive film.

In another embodiment, a method for fabricating a semiconductor device may include, but is not limited to, the following processes. A first groove is formed in a first insulating film. A first conductive film is formed on inner surfaces of the first groove. Second and third grooves are formed in the first insulating film to define the first conductive film into an electrode. The second and third grooves intersect the first groove.

In some cases, the method may further include, but is not limited to, forming a second insulating film on the first conductive film. The second insulating film is in the first groove. Forming the second and third grooves may include selectively removing the first conductive film and the second insulating film.

In some cases, the method may further include, but is not limited to, forming a second conductive film in contact with the first conductive film. The second conductive film is in the first groove.

In some cases, the method may further include, but is not limited to, forming a second insulating film on the first conductive film and the second conductive film. The second insulating film is in the first groove. Forming the second and third grooves may include selectively removing the first conductive film, the second conductive film, and the second insulating film.

In some cases, forming the second and third grooves may include, but is not limited to, forming a mask over the first conductive film and selectively removing the first insulating film and the first conductive film using the mask.

In some cases, forming the mask may include, but is not limited to, reducing a width of the mask.

In some cases, the method may further include, but is not limited to, forming a variable resistance material layer in contact with a top surface of the first conductive film.

In still another embodiment, a method for fabricating a semiconductor device may include, but is not limited to, the following processes. A first insulating film is formed over a semiconductor substrate. A first groove is formed in the first insulating film, the first groove extending in a first direction. A first conductive film is formed on a bottom surface and side surfaces of the first groove. A second groove is formed in the first insulating film to remove a part of the first conductive film and to define an electrode. The second groove extends in a second direction. The second groove intersects the first groove.

In some cases, the method may further include, but is not limited to, forming a second insulating film on the first conductive film. The second insulating film is in the first groove. Forming the second groove may include removing a part of the first conductive film and a part of the second insulating film.

In some cases, the method may further include, but is not limited to, forming a variable resistance material layer in contact with a top surface of the first conductive film.

In still another embodiment, a semiconductor device may include, but is not limited to, a phase change layer, a first conductor, and an electrode. The electrode is disposed between the phase change layer and the conductor. The electrode includes a first portion and a second portion. The first portion is thermally coupled with the phase change layer. The second portion is electrically coupled to the first conductor. The first portion is smaller in horizontal dimension than the second portion.

The variable resistance material as used herein may include, but is not limited to, phase change materials. The variable resistance material varies its resistivity upon receipt of heat energy. The phase change material switches between in crystalline and amorphous states upon receipt of heat energy. The phase change material is different in resistivity between in crystalline and amorphous states.

In some cases, the semiconductor device may include, but is not limited to, the first portion being close to the phase change layer.

In some cases, the semiconductor device may include, but is not limited to, the first portion being in contact with the phase change layer.

In some cases, the semiconductor device may further include, but is not limited to, a transistor electrically coupled to the electrode through the first conductor.

In some cases, the semiconductor device may include, but is not limited to, the phase change layer including a chalcogenide material.

In still another embodiment, a semiconductor device may include, but is not limited to, a phase change layer, a layered structure, and a first structure. The layered structure is adjacent to the phase change layer. The layered structure has a hole. The first structure is disposed in the hole. The first structure has an adjacent portion being adjacent to the phase change layer. The adjacent portion includes a first conductive portion and a non-conductive portion.

In some cases, the semiconductor device may include, but is not limited to, the adjacent portion being in contact with the phase change layer.

In some cases, the semiconductor device may include, but is not limited to, the non-conductive portion including an insulating material.

In some cases, the semiconductor device may include, but is not limited to, the adjacent portion further including a second conductive portion. The non-conductive portion is interposed between the first and second conductive portions.

In some cases, the semiconductor device may further include, but is not limited to, a transistor electrically coupled to the conductive portion.

In some cases, the semiconductor device may include, but is not limited to, the phase change layer including a chalcogenide material.

In some cases, the semiconductor device may include, but is not limited to, the first structure including a conductor under the adjacent portion. The conductor is in contact with non-conductive portion.

In still another embodiment, a semiconductor device may include, but is not limited to, a transistor, an insulating film, and a memory element. The insulating film is over the transistor. The insulating film has a hole. The memory element is electrically coupled to the transistor. The memory element includes a first electrode, a second electrode, and a phase change layer. The first electrode is in the hole. The first electrode includes a first conductive portion on a first side surface of the hole, a second conductive portion on a second side surface of the hole, and a third conductive portion on a bottom surface of the hole. The second electrode is over the first electrode. The phase change layer is interposed between the first and second electrodes.

In some cases, the semiconductor device may include, but is not limited to, the phase change layer in contact with a top surface of the first electrode.

In some cases, the semiconductor device may further include, but is not limited to, a second insulating film over the third conductive portion. The second insulating film and the first electrode fill the hole.

In some cases, the semiconductor device may include, but is not limited to, the second insulating film is in contact with the phase change layer.

In some cases, the semiconductor device may include, but is not limited to, the phase change layer including a chalcogenide material.

In some cases, the semiconductor device may include, but is not limited to, the memory element further including a first conductor on the third conductive portion.

In still another embodiment, a method for fabricating a semiconductor device may include, but is not limited to, the following processes. A first insulating film is formed over a semiconductor substrate. A first groove is formed in a first direction in the first insulating film. A first conductive film is formed on a bottom surface and side surfaces of the first groove. A second groove is formed in a second direction to remove a part of the first conductive film. The second direction intersects with the first direction. A variable resistance material layer is formed in contact with a top surface of the first conductive film.

In some cases, the method may further include, but is not limited to, forming a second conductive film in contact with the first conductive film.

In some cases, forming the second groove may include, but is not limited to, forming a hard mask over the first conductive film, and etching a part of the first conductive film.

In some cases, forming the hard mask may include, but is not limited to, etching a side surface of the hard mask.

In some cases, the method may further include, but is not limited to, forming a second insulating film over the first conductive film.

In some cases, forming the second groove may include, but is not limited to, separating the first conductive film by the second groove to form a plurality of electrodes.

Hereinafter, a semiconductor device according to an embodiment of the invention will be described in detail with reference to the drawings. In the embodiment, a phase-change memory (PRAM) will be described. In the drawings used for the following description, to easily understand characteristics, there is a case where characteristic parts are enlarged and shown for convenience' sake, and ratios of constituent elements may not be the same as in reality. Materials, sizes, and the like exemplified in the following description are just examples and may be different from those of an actual structure, electrode structure, and semiconductor device. The invention is not limited thereto and may be appropriately modified within a scope which does not deviate from the concept of the invention.

### First Embodiment

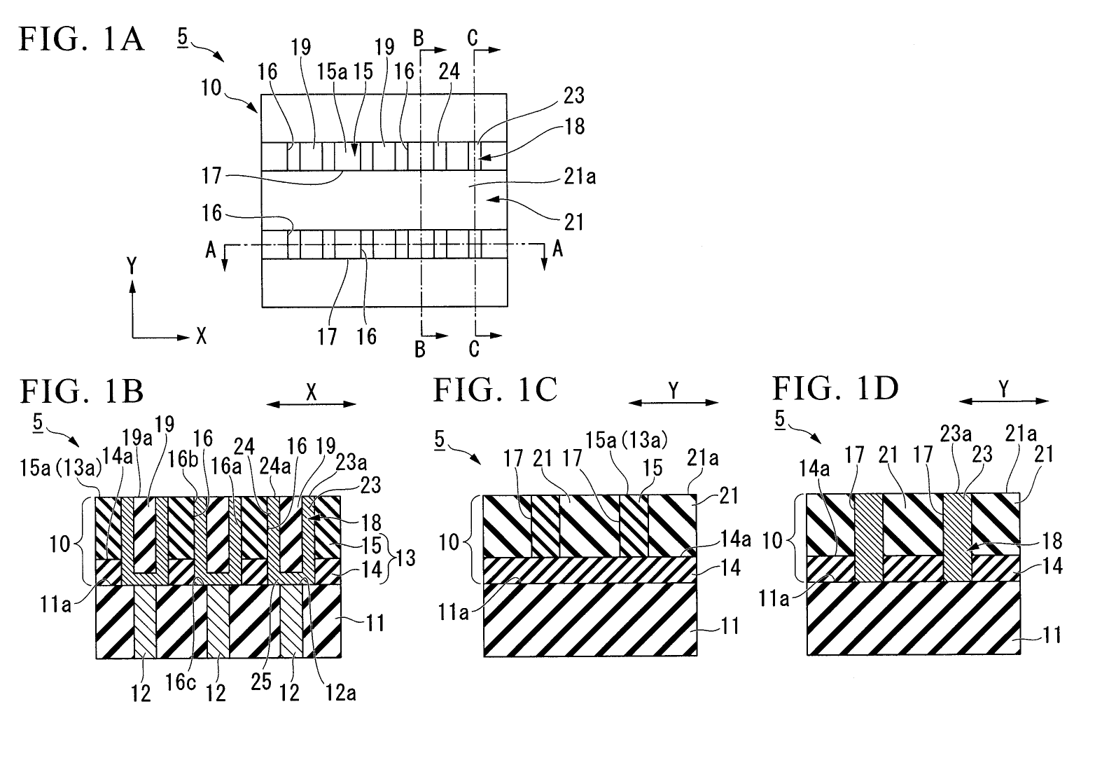

FIGS. 1A to 1D are schematic views of a structure including an electrode structure according to a first embodiment of the present invention. FIG. 1A is a plan view of the structure, FIG. 1B is a cross-sectional view taken along line A-A of FIG. 1A, FIG. 1C is a cross-sectional view taken along line B-B of FIG. 1A, and FIG. 1D is a cross-sectional view taken along line C-C of FIG. 1A.

Referring to FIGS. 1A to 1D, there is a structure 5 which includes an electrode structure 10, a first insulating film 11, and a contact plug 12.

The electrode structure 10 includes a silicon nitride film 14 and a silicon oxide film 15, a first groove 16, a second groove 17, an electrode 18, a second insulating film 19, and a third insulating film 21. The silicon nitride film 14 and the silicon oxide film 15 are included in a first interlayer insulating film 13.

The silicon nitride film 14 is formed on a top surface 11a of the first insulating film 11. The silicon oxide film 15 is formed on a top surface 14a of the silicon nitride film 14. For example, a Si₃N₄ film with a thickness of, for example, 10 to 30 nm may be used as the silicon nitride film 14.

The first groove 16 penetrates the silicon nitride film 14 and the silicon oxide film 15. The first groove 16 extends in a Y direction. A plurality of first grooves 16 are arranged at predetermined intervals in an X direction. A bottom surface 16c of the first groove 16 may include an exposed top surface 12a of the contact plug 12 and a top surface 11a of the first insulating film 11.

In addition, the plurality of first grooves 16 intersect with a plurality of second grooves 17 at a plurality of positions as shown in FIGS. 1A to 1D. Also, the plurality of second grooves 17 extend in the X direction. While FIGS. 1A to 1D illustrate an example where the first grooves 16 intersect with the second grooves 17 at an angle of 90°, which is not limited thereto.

The plurality of second grooves 17 penetrate the silicon oxide film 15. The plurality of second grooves 17 extend in the X direction. The second grooves 17 are arranged at predetermined intervals in the X direction. Each of bottom surfaces of the second grooves 17 may include the top surface 14a of the silicon nitride film 14.

The electrode 18 is formed in the first groove 16, which does not intersect with the second groove 17.

The electrode 18 has a U shape. The electrode 18 includes a first conductive film (e.g., a metal film such as a titanium nitride (TiN) film). The electrode 18 includes a first conductive portion 23, a second conductive portion 24, and a third conductive portion 25.

The first conductive portion 23 is formed on a first side surface 16a of the first groove 16. A top surface 23a of the first conductive portion 23 is exposed by the first insulating film 11 and the silicon oxide film 15.

The top surface 23a of the first conductive portion 23 is aligned in level to a top surface 15a of the silicon oxide film 15. For example, when the variable resistance material layer (not shown) is disposed on the electrode structure 10, the top surface 23a of the first conductive portion 23 is in contact with the variable resistance material layer.

The second conductive portion 24 is formed on a second side surface 16b of the first groove 16. The first side surface 16a and the second side surface 16b are opposed to each other. The second conductive portion 24 is disposed to face the first conductive portion 23.

A top surface 24a of the second conductive portion 24, which corresponds to an end portion of the electrode 18, is shown on the surface of the silicon oxide film 15. The top surface 24a of the second conductive portion 24 is aligned in level to the top surface 15a of the silicon oxide film 15. For example, when the variable resistance material layer (not shown) is disposed on the electrode structure 10, the top surface 24a of the second conductive portion 24 is in contact with the variable resistance material layer.

The third conductive portion 25 is formed on the bottom surface 16c of the first groove 16, which is disposed between the first conductive portion 23 and the second conductive portion 24. The top surfaces 23a and 24a are smaller in horizontal dimension than a bottom surface of the third conductive portion 25. The first, second, and third conductive portions 23, 24, and 25 are united with each other to form a single conductive film performing as the electrode 18.

The second insulating film 19 fills the plurality of first grooves 16 in which the electrodes 18 has been formed. A top surface 19a of the second insulating film 19 is aligned in level to the top surfaces 23a and 24a of the first and second conductive portions 23 and 24 and the top surface 15a of the silicon oxide film 15.

For example, a SiO₂ film may be used as the second insulating film 19. A spin-on-dielectrics (SOD) film may be preferably used as the second insulating film 19. The spin-on-dielectrics (SOD) film is a coating-based insulating film formed by using a spinner method which has a high gap-filling property.

The third insulating film 21 fills the plurality of second grooves 17. A top surface 21a of the third insulating film 21 is aligned in level to the top surface 15a of the silicon oxide film 15.

For example, a SiO₂ film may be used as the third insulating film 21. For example, an SOD film may be used as the third insulating film 21. The SOD film is a coating-based insulating film formed using a spinner method which has a high gap-filling property.

A plurality of contact plugs 12 penetrate the first insulating film 11. For example, a SiO₂ film may be used as the first insulating film 11.

The contact plugs 12 are arranged at predetermined intervals in the Y direction, which is the first direction. Thereby, top surfaces 12a of the contact plugs 12 are aligned in level the first insulating film 11.

According to the electrode structure of the present embodiment, the electrode 18 disposed in the first groove 16 has a U shape. By virtue of this, the areas of the top surfaces 23a and 24a of the first and second conductive portions 23 and 24 can be shrunken. Thus, for example, when the variable resistance material layer (not shown) contacting the top surfaces 23a and 24a of the first and second conductive portions 23 and 24 is formed on the electrode structure 10, a contact area between the electrode 18 and the variable resistance material layer can be shrunken.

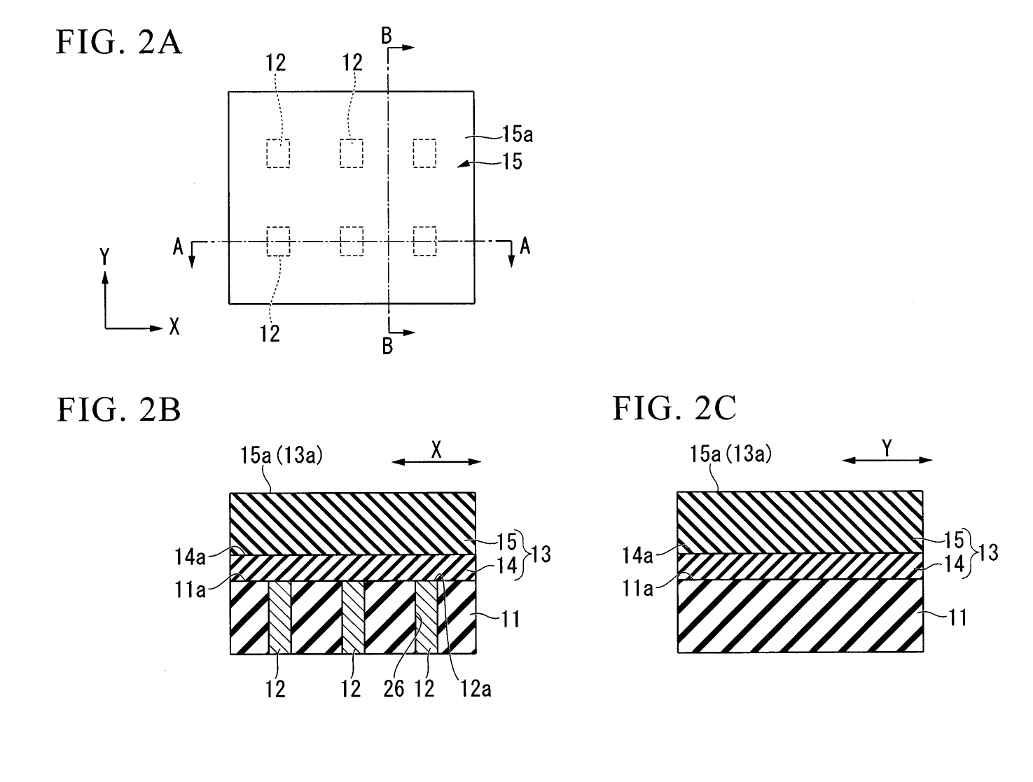

A process of fabricating a structure including an electrode structure according to an embodiment of the present invention will be described with reference to FIGS. 2A through 13D. In FIGS. 2A through 13D, the same reference numerals are used to denote the same components as the structure 5 of FIGS. 1A to 1D.

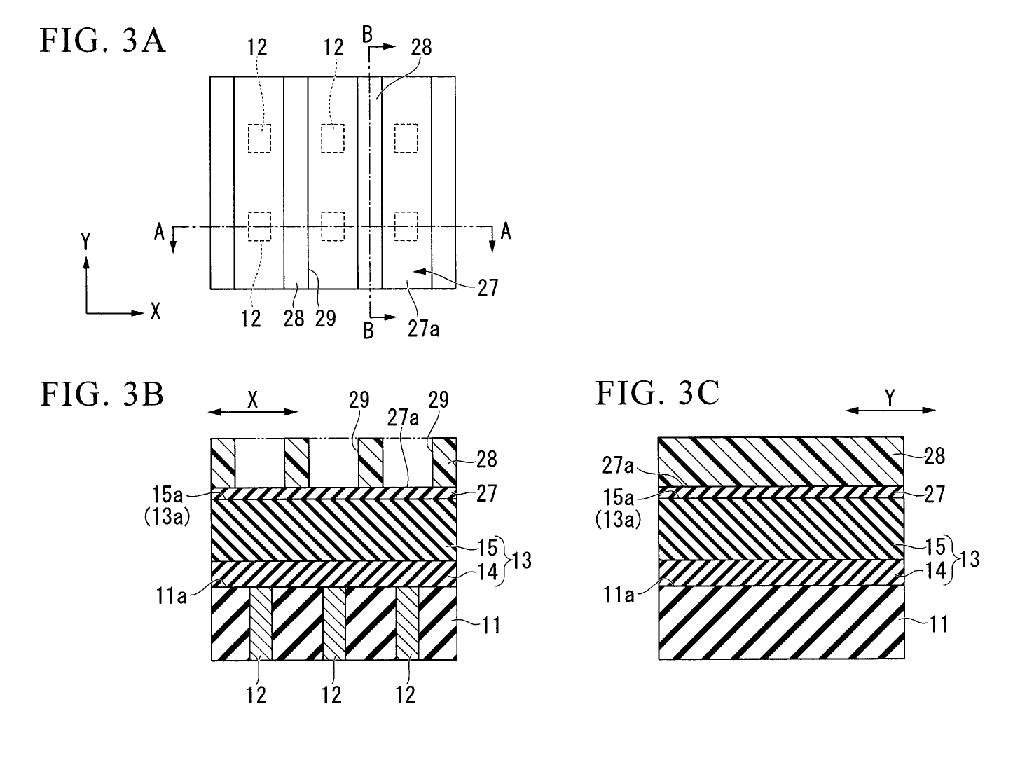

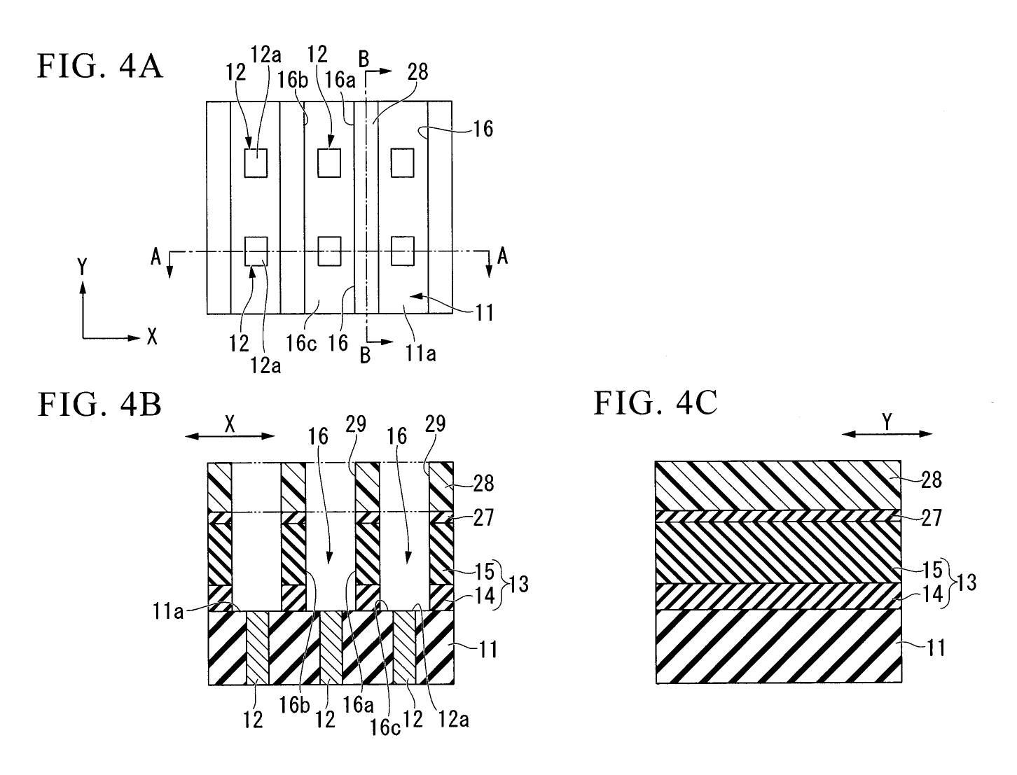

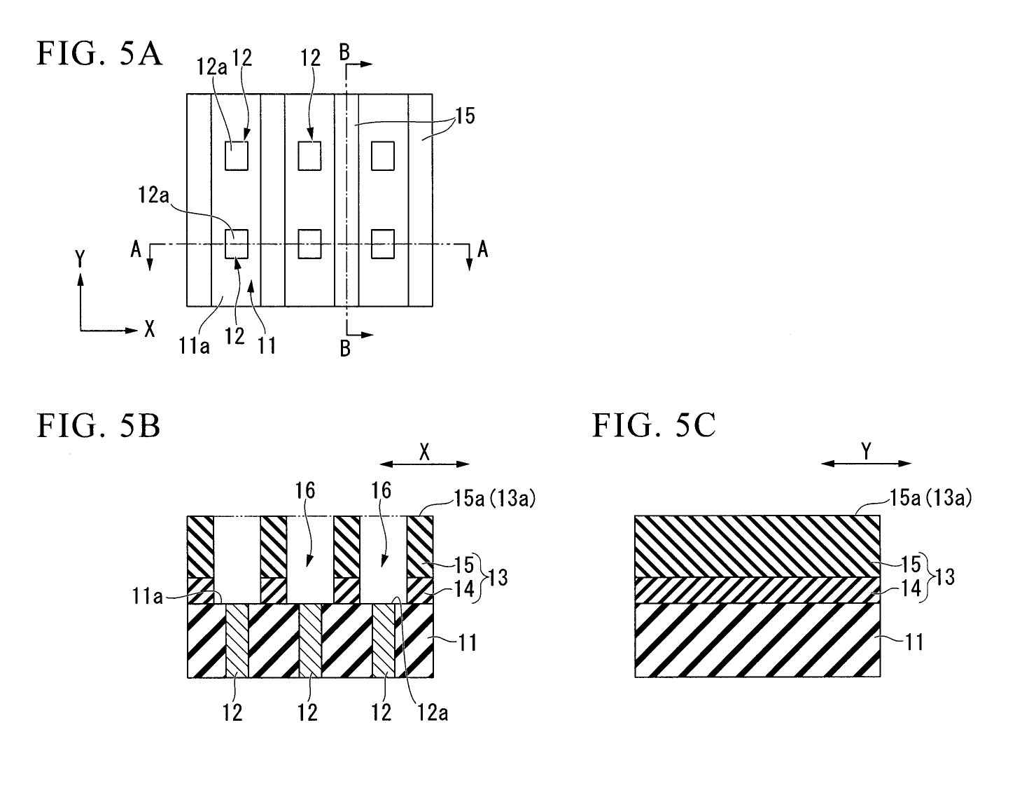

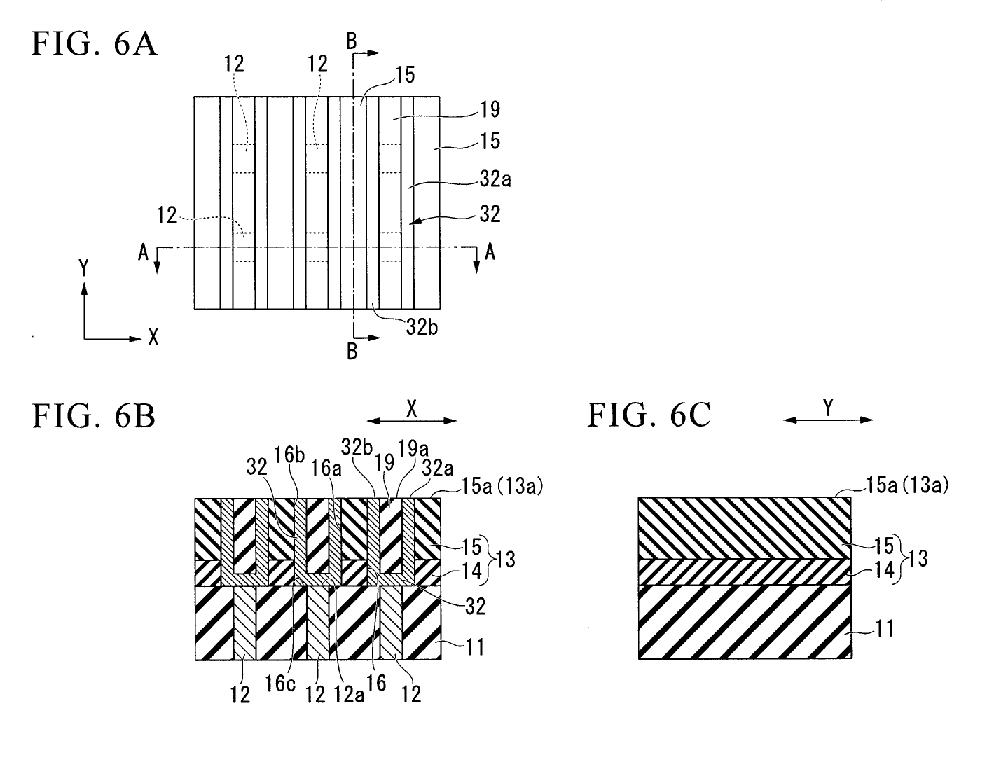

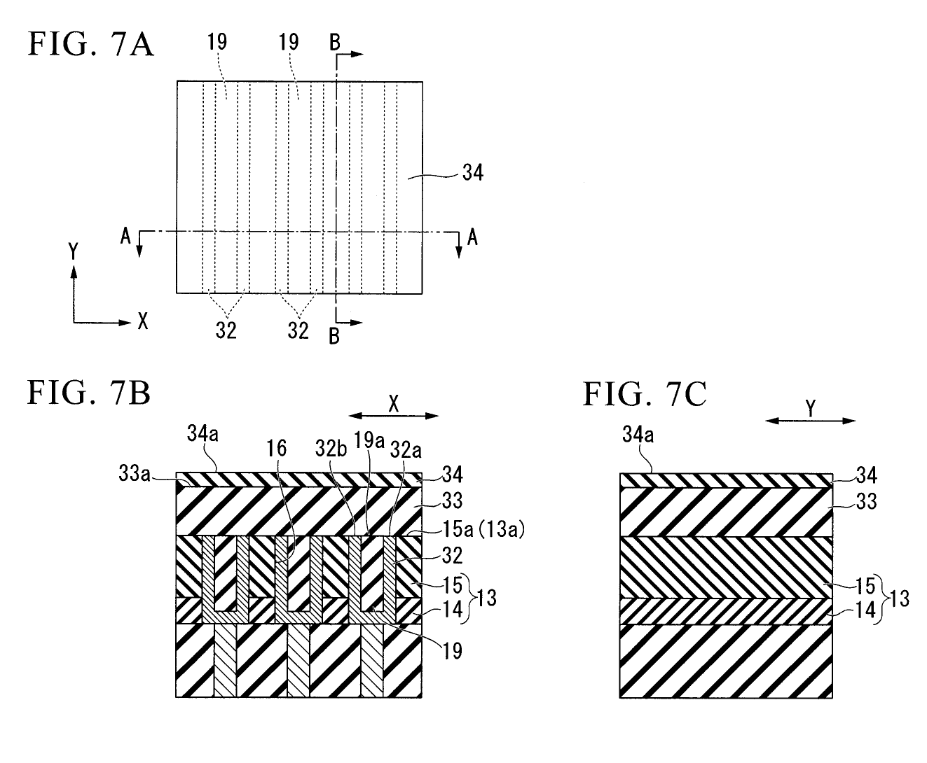

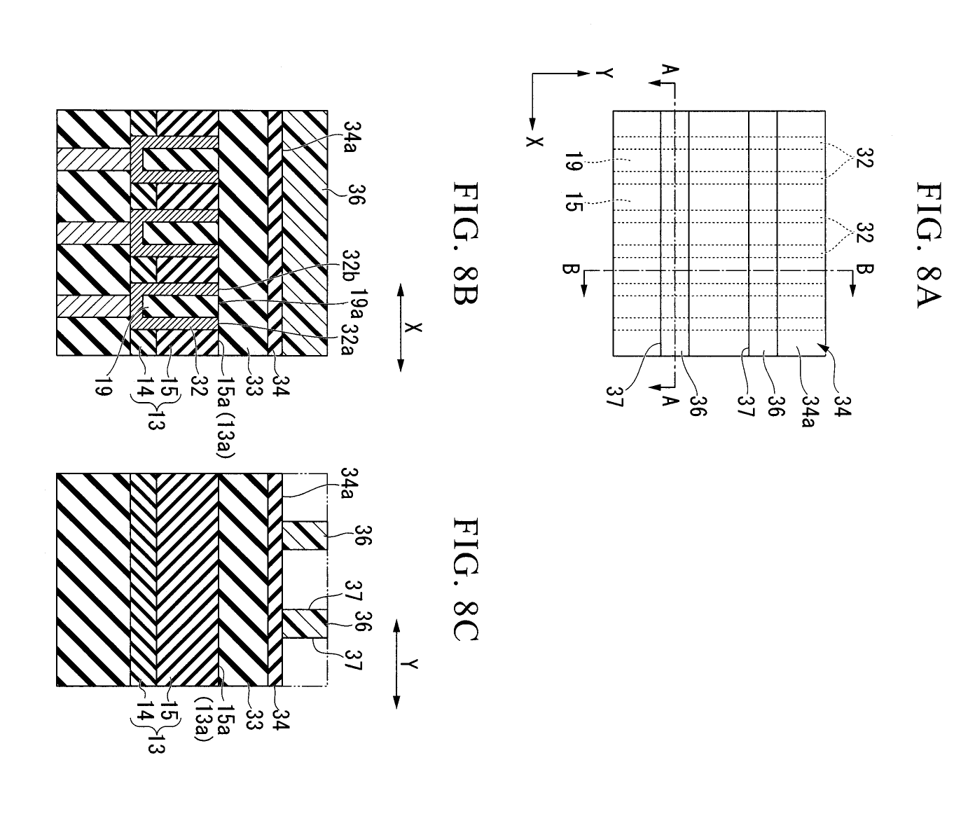

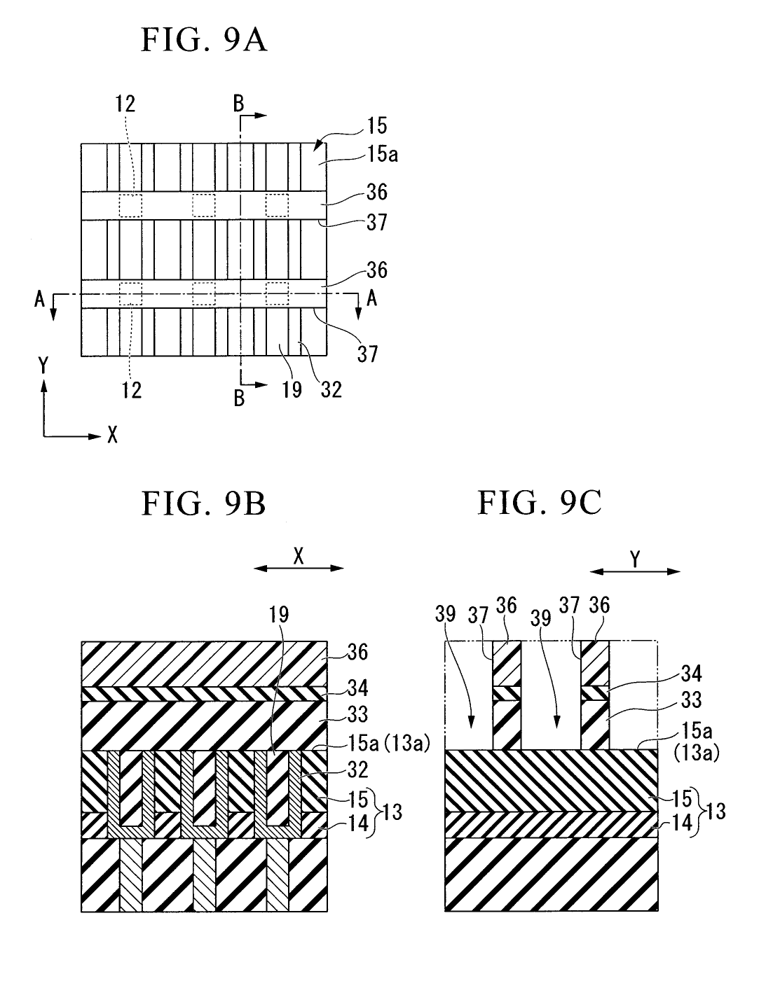

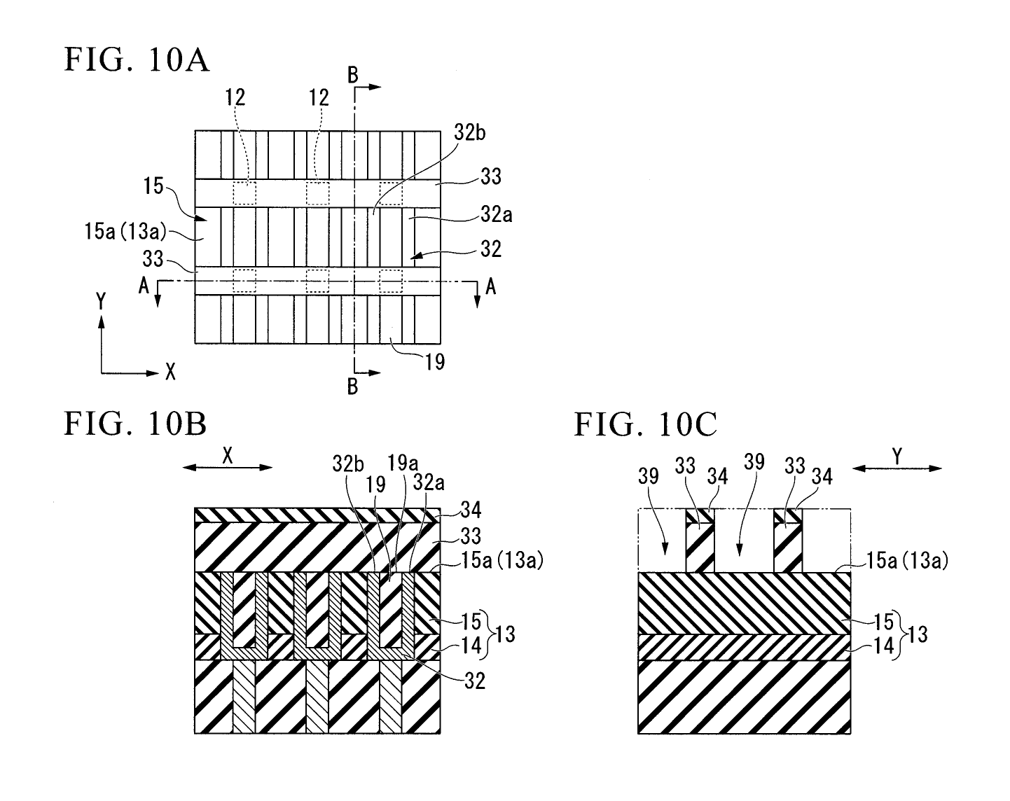

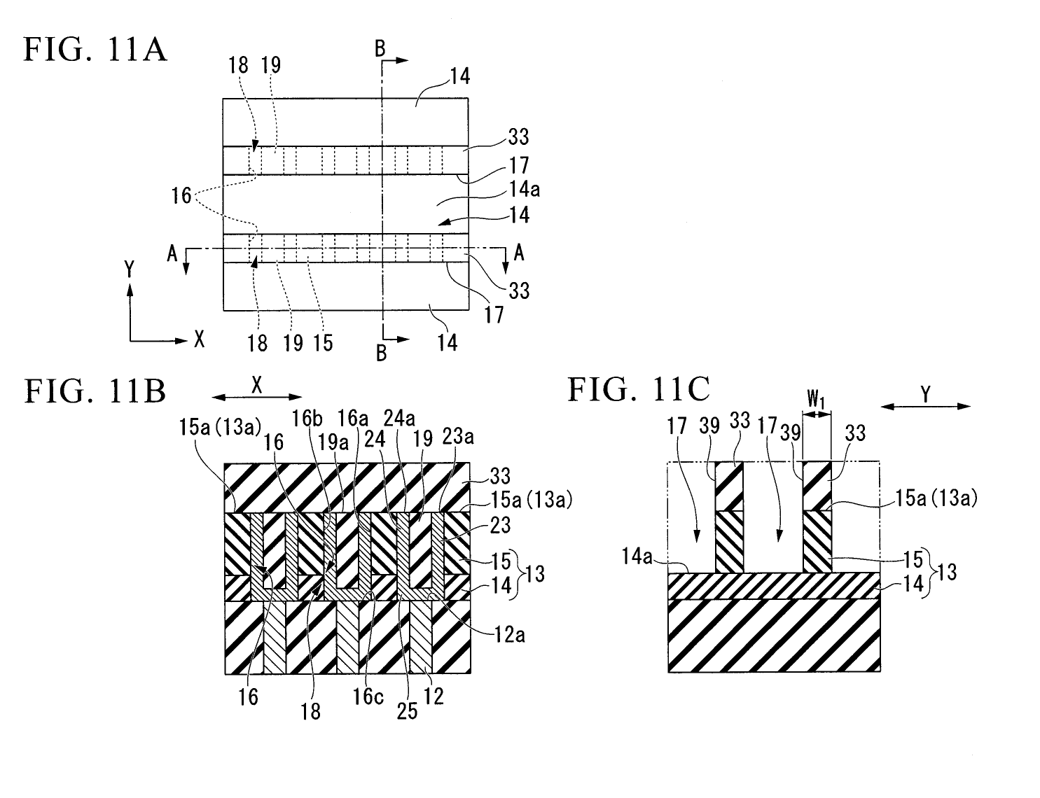

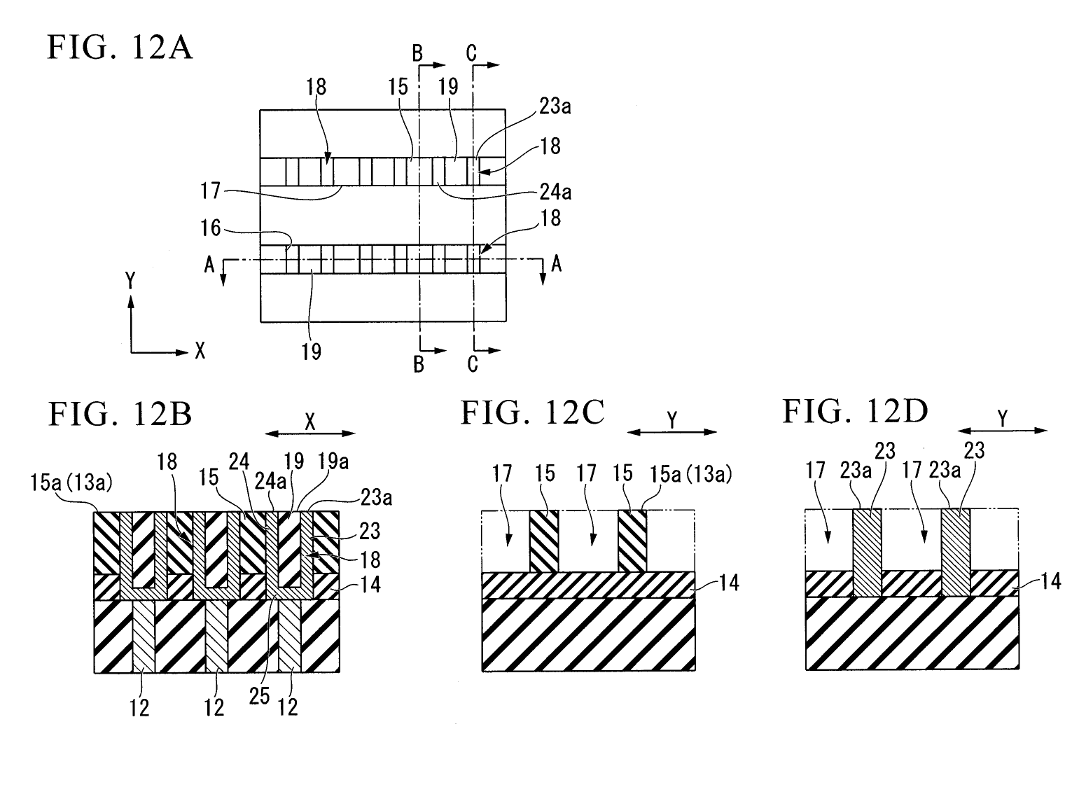

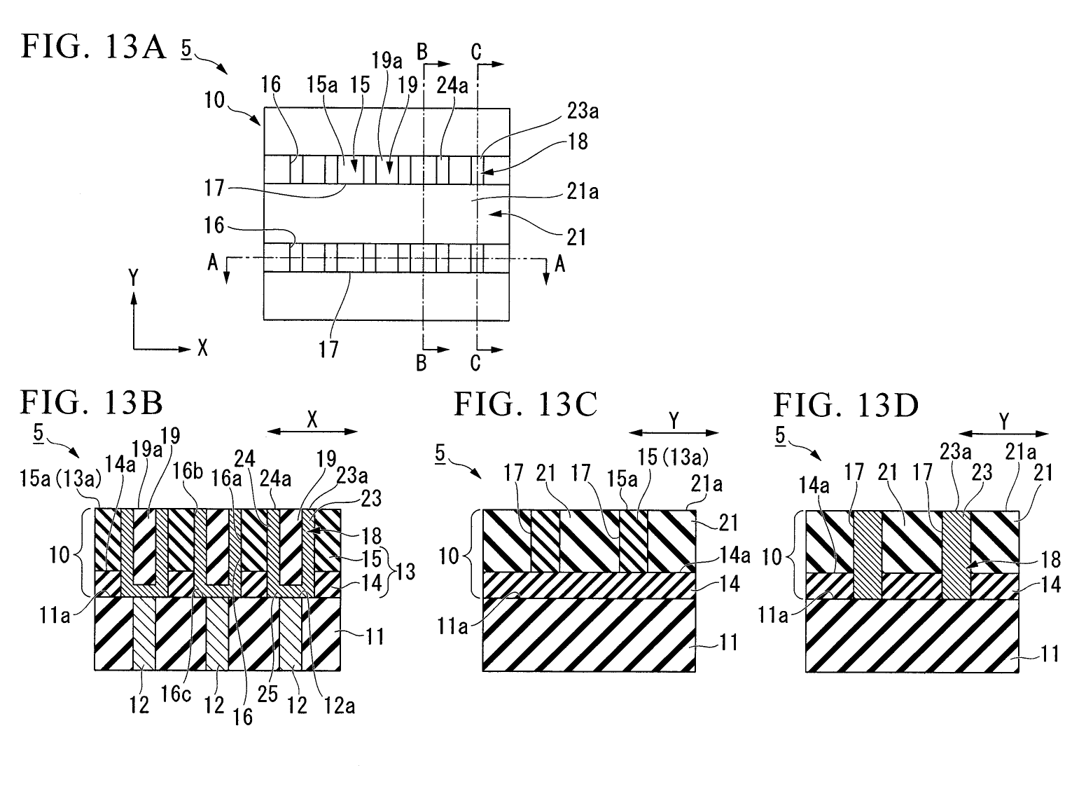

FIG. 2A is a plan view of the structure, FIG. 2B is a cross-sectional view taken along line A-A of FIG. 2A, and FIG. 2C is a cross-sectional view taken along line B-B of FIG. 2A. FIG. 3A is a plan view of the structure, FIG. 3B is a cross-sectional view taken along line A-A of FIG. 3A, and FIG. 3C is a cross-sectional view taken along line B-B of FIG. 3A. FIG. 4A is a plan view of the structure, FIG. 4B is a cross-sectional view taken along line A-A of FIG. 4A, and FIG. 4C is a cross-sectional view taken along line B-B of FIG. 4A. FIG. 5A is a plan view of the structure, FIG. 5B is a cross-sectional view taken along line A-A of FIG. 5A, and FIG. 5C is a cross-sectional view taken along line B-B of FIG. 5A. FIG. 6A is a plan view of the structure, FIG. 6B is a cross-sectional view taken along line A-A of FIG. 6A, and FIG. 6C is a cross-sectional view taken along line B-B of FIG. 6A. FIG. 7A is a plan view of the structure, FIG. 7B is a cross-sectional view taken along line A-A of FIG. 7A, and FIG. 7C is a cross-sectional view taken along line B-B of FIG. 7A. FIG. 8A is a plan view of the structure, FIG. 8B is a cross-sectional view taken along line A-A of FIG. 8A, and FIG. 8C is a cross-sectional view taken along line B-B of FIG. 8A. FIG. 9A is a plan view of the structure, FIG. 9B is a cross-sectional view taken along line A-A of FIG. 9A, and FIG. 9C is a cross-sectional view taken along line B-B of FIG. 9A. FIG. 10A is a plan view of the structure, FIG. 10B is a cross-sectional view taken along line A-A of FIG. 10A, and FIG. 10C is a cross-sectional view taken along line B-B of FIG. 10A. FIG. 11A is a plan view of the structure, FIG. 11B is a cross-sectional view taken along line A-A of FIG. 11A, and FIG. 11C is a cross-sectional view taken along line B-B of FIG. 11A. FIG. 12A is a plan view of the structure, FIG. 12B is a cross-sectional view taken along line A-A of FIG. 12A, FIG. 12C is a cross-sectional view taken along line B-B of FIG. 12A, and FIG. 12D is a cross-sectional view taken along line C-C of FIG. 12A. FIG. 13A is a plan view of the structure, FIG. 13B is a cross-sectional view taken along line A-A of FIG. 13A, FIG. 13C is a cross-sectional view taken along line B-B of FIG. 13A, and FIG. 13D is a cross-sectional view taken along line C-C of FIG. 13A.

The method of fabricating the electrode structure 10 according to the first embodiment when the structure 5 is fabricated as an example will be described with reference to FIGS. 2A through 13D.

To begin with, a process shown in FIGS. 2A to 2C includes forming a first insulating film 11, forming a plurality of through holes 26 in the first insulating film 11, and forming contact plugs 12 to fill the plurality of through holes 26. A SiO₂ film may be used as the first insulating film 11, for example. Also, the contact plugs 12 may be formed of, for example, a stack film obtained by sequentially stacking a Ti film, a TiN film, and a tungsten (W) film.

Thereafter, in the case where top surfaces of the contact plugs 12 protrude from a top surface 11a of the first insulating film 11, protruding portions (unnecessary portions) of the contact plugs 12 may be removed using a polishing process.

Thus, the top surface 11a of the first insulating film 11 is aligned in level to top surfaces 12a of the contact plugs 12. The removal of the unnecessary portions of the contact plugs 12 may be performed using, for example, a chemical mechanical polishing (CMP) technique.

Subsequently, a silicon nitride film 14 is formed to cover the top surface 11a of the first insulating film 11 and the top surfaces 12a of the contact plugs 12. Then, a silicon oxide film 15 is formed to cover a top surface 14a of the silicon nitride film 14 (first interlayer insulating film forming process).

Thus, a first interlayer insulating film 13 including the silicon nitride film 14 and the silicon oxide film 15 is formed. For example, a Si₃N₄ film with a thickness of, for example, 10 to 30 nm may be used as the silicon nitride film 14. Also, for example, a SiO₂ film with a thickness of 70 nm may be used as the silicon oxide film 15.

Subsequently, a process shown in FIGS. 3A to 3C includes forming a first anti-reflection film 27 to cover a top surface 15a of the silicon oxide film 15, or a top surface 13a of the first interlayer insulating film 13.

The first anti-reflection film 27 may be, for example, a bottom anti-reflection coating (BARC) film. For example, the formation of the first anti-reflection film 27 may include coating an acryl-based organic material on the top surface 15a of the silicon oxide film 15 (which is the top surface 13a of the first interlayer insulating film 13), with a thickness of 30 nm to 100 nm.

Thereafter, a first resist pattern 28 serving as an etch mask for the formation of first grooves 16 (refer to FIGS. 1A to 1D) is formed on a top surface 27a of the first anti-reflection film 27 by a photolithography technique.

In this case, the first resist pattern 28 has a plurality of openings 29 under which the top surface 27a of the first anti-reflection film 27 are positioned. The first grooves 16 (refer to FIGS. 1A to 1D) will be formed under the plurality of openings 29.

The first resist pattern 28 has the plurality of openings 29 extending in the Y direction. Also, the plurality of openings 29 overlap with the top surfaces 12a of the plurality of contact plugs 12. The plurality of contact plugs 12 are aligned in the Y direction. The silicon nitride film 14 is disposed over the plurality of contact plugs 12. The silicon oxide film 15 is disposed over the silicon nitride film 14. The first anti-reflection film 27 is disposed over the silicon oxide film 15. The first resist pattern 28 with the plurality of openings 29 is disposed over the first anti-reflection film 27.

Specifically, formation of the first resist pattern 28 includes coating a resist film (not shown) on the top surface 27a of the first anti-reflection film 27, exposing the resist film to light through a reticle disposed in an exposure apparatus (not shown), and developing the exposed resist film.

As described above, the resist film (not shown) is applied on the first anti-reflection film 27. The resist film (not shown) is exposed to light to form the first resist pattern 28 on the first anti-reflection film 27. If the first anti-reflection film 27 were not formed on the silicon oxide film 15, the light would be reflected by interface between the silicon oxide film 15 and the resist film (not shown). The first anti-reflection film 27 may reduce reflected light which reaches the resist film. Thus, the openings 29 can be precisely formed so that the openings 29 have a desired shape, particularly a desired width defined as a dimension in X-direction.

When an immersion exposure apparatus using an argon fluoride (ArF) laser as a light source is adopted as the exposure apparatus for forming the first resist pattern 28, the opening 29 may have a width of, for example, 40 nm to 45 nm in X-direction.

Thereafter, a process shown in FIGS. 4A to 4C includes removing portions of the first interlayer insulating film 13 and the first anti-reflection film exposed by a bottom of the openings 29 through an anisotropic etching process (e.g., dry etching process) using the first resist pattern 28. Thus, a plurality of first grooves 16 are formed in the first interlayer insulating film 13 to expose the top surface 11a of the first insulating film 11 and the top surfaces 12a of the plurality of contact plugs 12 disposed in the Y direction (first groove forming process).

The plurality of first grooves 16 are formed to extend in the Y direction. Each of the first grooves 16, which is required to form the corresponding one of a plurality of electrodes 18 (refer to FIGS. 1A to 1D), has a first side surface 16a, a second side surface 16b, and a bottom surface 16c. The first side surface 16a and the second side surface 16b are opposed to each other. The plurality of first grooves 16 are formed to penetrate the first interlayer insulating film 13.

Thus, by forming the plurality of first grooves 16 to penetrate the first interlayer insulating film 13, the contact plugs 12 (refer to FIGS. 1A to 1D) disposed under the electrode structure 10 may be connected to portions corresponding to bottoms of the plurality of electrodes 18.

When the dry etching process is used as the anisotropic etching process, for example, a magnetron reactive-ion-etching (RIE) apparatus may be used as an etching apparatus.

In this case, the etching process may be divided into a first anti-reflection film etching step of etching the first anti-reflection film 27 and a first interlayer-insulating-film etching step of etching the first interlayer insulating film 13.

In the first anti-reflection film etching step, the etching process is performed using, for example, a mixture of CF₄ gas supplied at a flow rate of, for example, 100 sccm and CHF₃ gas supplied at a flow rate of, for example, 50 sccm as an etching gas under a pressure of 60 mTorr at a radio-frequency (RF) power of 500 W.

Also, in the first-interlayer-insulating-film etching step, the etching process is performed using, for example, a mixture of CF₄ gas supplied at a flow rate of, for example, 100 sccm, CH₂F₂ gas supplied at a flow rate of, for example, 30 sccm, and O₂ gas supplied at a flow rate of, for example, 50 sccm as an etching gas under a pressure of 60 mTorr at an RF power of 500 W.

As described above, the first grooves 16 is formed. The plurality of electrodes 18 are then disposed in the first grooves 16. Using an anisotropic etching process, the first grooves 16 having a smaller width of, for example, 40 to 45 nm in X-direction can be easily formed because the first grooves 16 have a greater width in Y-direction.

In other words, since an aspect ratio (=a ratio of the depth of the first groove 16 to the width of the first groove 16 in Y-direction) of the first groove 16 is smaller than an aspect ratio (=a ratio of the depth of a contact hole to the diameter of the contact hole) of the contact hole formed by the related art, the first grooves 16 having a small width in X-direction may be easily formed using an anisotropic etching process.

In addition, the width in X-direction of the plurality of electrodes 18 is reduced by reducing the width of the first grooves 16 in X-direction, thereby miniaturizing the dimension of the plurality of electrodes 18 in X-direction.

The process shown in FIGS. 3A, 3B, 3C, 4A, 4B, and 4C corresponds to the first groove forming process.

Subsequently, a process shown in FIGS. 5A to 5C is performed, which includes removing the first resist pattern 28 and the first anti-reflection film 27 shown in FIGS. 4A to 4C.

A process shown in FIGS. 6A to 6C is then performed, which includes forming a first conductive film 32 to cover the first side surface 16a, the second side surface 16b, and bottom surfaces 16c of the plurality of first grooves 16 (first-conductive-film forming process).

Thus, portions of the first conductive film 32 formed on the bottom surfaces 16c of the first grooves 16 are in contact with the top surfaces 12a of the plurality of contact plugs 12.

The first-conductive-film forming process is performed in which the first conductive film 32 is formed to provide a gap between the first conductive film 32 formed on the first side surface 16a of the first groove 16 and the first conductive film 32 formed on the second side surface 16b thereof.

For example, when the first grooves 16 have a width of 45 nm in X-direction, the first conductive film 32 may be formed to a thickness of, for example, 10 nm.

In the first-conductive-film forming process, the first conductive film 32 is formed using, for example, a chemical vapor deposition (CVD) process.

Thus, the first conductive film 32 may be formed to a uniform thickness on the first and second side surfaces 16a and 16b and bottom surfaces 16c of the plurality of first grooves 16 by using the CVD process.

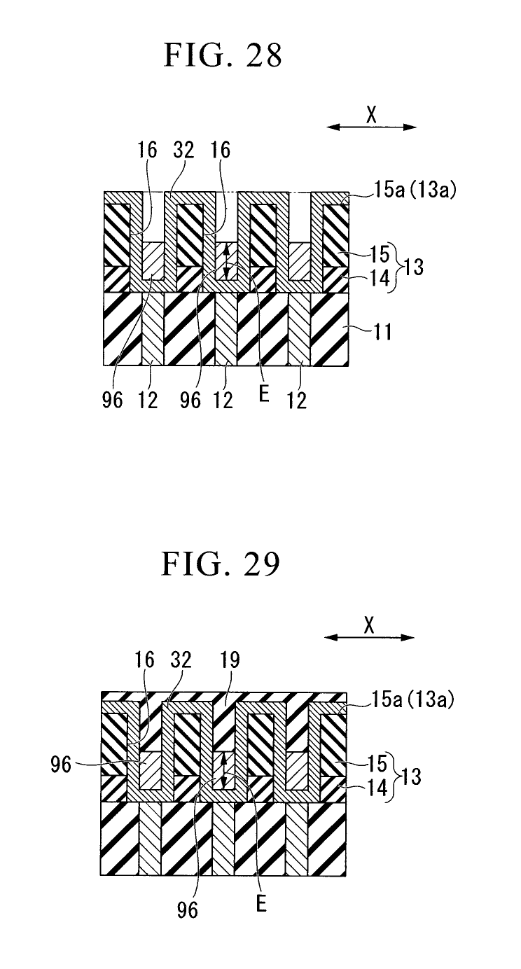

In addition, when the first conductive film 32 is formed by using a CVD process, the first conductive film 32 (not shown) is also formed on the top surface 15a of the silicon oxide film 15 (refer to the first conductive film 32 shown in FIG. 28).

The first conductive film 32 may be, but is not limited to, a TiN film. A metal film other than the TiN film may be also used.

Thereafter, the plurality of first grooves 16 in which the first conductive film 32 is formed are filled with the second insulating film 19 (second insulating film filling process).

The second insulating film 19 may be, but is not limited to, a silicon oxide (SiO₂) film or a silicon nitride film. When the silicon oxide film is used as the second insulating film 19, the second insulating film 19 may be formed by using, for example, a spinner process or an atomic layer deposition (ALD) process.

Thus, the plurality of first grooves 16 are filled with the coating-based second insulating film 19 using a spinner technique to obtain a good gap filling property of the coating-based second insulating film 19, thereby preventing generation of voids in the second insulating film 19.

When a silicon nitride film is used as the second insulating film 19, the second insulating film 19 may be formed by using, for example, a low-pressure CVD (LP-CVD) process.

In addition, in the second insulating film filling process, the second insulating film 19 is also formed on a portion of the first conductive film 32 disposed on the top surface 15a of the silicon oxide film 15 (refer to the second insulating film 19 of FIG. 29).

Thereafter, portions of the first conductive film 32 and the second insulating film 19 protruding from the top surface 15a of the silicon oxide film 15 are removed (first conductive film and second insulating film removing process). The top surface 15a of the silicon oxide film 15 corresponds to the top surface 13a of the first interlayer insulating film 13.

In the first conductive film and second insulating film removing process, the protruding portions of the first conductive film 32 and the second insulating film 19 from the top surface 15a of the silicon oxide film 15 are removed using, for example, an etch-back process or a CMP process.

Thus, as shown in FIG. 6B, the top surface 15a of the silicon oxide film 15, the top surface 19a of the second insulating film 19, and top surfaces 32a and 32b of the first conductive film 32 have the same level.

Thereafter, a base material for a hard mask layer 33 is deposited on the top surface 15a of the silicon oxide film 15, the top surface 19a of the second insulating film 19, and the top surfaces 32a and 32b of the first conductive film 32 as shown in FIGS. 7A to 7C. In the process shown in FIGS. 7A to 7C, a plurality of openings are not formed in the hard mask layer 33 yet. The base material film for the hard mask layer 33 may be an amorphous carbon layer with a thickness of, for example, 100 nm formed by a CVD process using a hydrocarbon such as methane (CH₄).

Thereafter, a second anti-reflection film 34 is formed on the top surface 33a of the hard mask layer 33 shown in FIGS. 7B and 7C. For example, an anti-reflection film may be used as the second anti-reflection film 34. Also, the anti-reflection film may be, for example, a silicon-oxynitride (SiON)-containing film with a thickness of, for example, 30 nm.

Thereafter, a second resist pattern 36 is formed on a top surface 34a of the second anti-reflection film 34 using a photolithography technique as shown in FIGS. 8A to 8C. The second resist pattern 36 serves as an etching mask used for forming a plurality of openings in the hard mask layer 33.

In this case, a plurality of openings 37 are formed in parts of the second resist pattern 36 corresponding to regions where the second grooves 17 (refer to FIGS. 1A to 1D) will be formed. The top surface 34a of the second anti-reflection film 34 is shown through the plurality of openings 37. The plurality of openings 37 extend in the X direction.

The second resist pattern 36 is formed to cover portions of the top surface 34a of the second anti-reflection film 34. The portions of the top surface 34a are disposed on a portion of the second insulating film 19 corresponding to a region where the electrode 18 will be formed.

Specifically, the second resist pattern 36 having the plurality of openings 37 is formed as follows. A resist film (not shown) is coated on the top surface 34a of the second anti-reflection film 34. The resist film is exposed through a reticle (not shown) provided with an exposure apparatus (not shown). The exposed resist film is developed.

Thus, the second resist pattern 36 is formed on the second anti-reflection film 34. The second anti-reflection film 34 inhibits light from being reflected by the hard mask layer 33, whereby the light is hard to reach the resist film. The opening 37 having a desired shape (for example, a desired width of the opening 37 in Y-direction) can be precisely formed.

Thus, in processes shown in FIGS. 10A to 10C, which will be described later, a plurality of openings 39 having a desired shape are formed in the hard mask layer 33.

Thereafter, as shown in FIGS. 9A to 9C, portions of the hard mask layer 33 and the second anti-reflection film 34 shown through the plurality of openings 37 are removed. At this time, an anisotropic etching process using the second resist pattern 36 having the plurality of openings 37 as a mask is employed. Thereby, the plurality of openings 39 extending in the X direction are formed in the hard mask layer 33. Here, the top surface 15a of the silicon oxide film 15 can be seen through the plurality of openings 39. The plurality of openings 39 intersect in an axis extending in the Y direction.

In the process shown in FIGS. 9A to 9C, when a dry etching process is employed as the anisotropic etching process, for example, a magnetron RIE apparatus may be used as an etching apparatus.

In this case, the dry etching process may be divided into a second anti-reflection film etching step of etching the second anti-reflection film 34 and a hard mask layer etching step of etching the hard mask layer 33.

In the second anti-reflection film etching step, for example, the dry etching process is performed using a mixture of CF₄ gas (supplied at a flow rate of, for example, 240 sccm) and O₂ gas (supplied at a flow rate of, for example, 5 sccm) as an etching gas under a pressure of 40 mTorr at an RF power of 400 W.

In the hard mask layer etching step, when an amorphous carbon film is used as the hard mask layer 33, the dry etching process is performed using a mixture of Ar gas (supplied at a flow rate of, for example, 150 sccm) and O₂ gas (supplied at a flow rate of, for example, 90 sccm) as an etching gas under a pressure of 15 mTorr at an RF power of 500 W.

When an immersion exposure apparatus (not shown) using an ArF laser as a light source is used as the exposure apparatus for forming the second resist pattern 36, the openings 39 with a width of, for example, 40 nm to 45 nm in Y-direction may be formed in the hard mask layer 33.

The case where the amorphous carbon film is used as a base material film for the hard mask layer 33 is explained. The second resist pattern 36 and the hard mask layer 33 are removed during the dry etching process. However, by forming the second anti-reflection film 34 using a SiON-containing film, it is possible to maintain a mask shape of the second resist pattern 36.

The second anti-reflection film 34 is formed of a material having a low etching rate in the dry etching process of the amorphous carbon film. Thereby, the second anti-reflection film 34 may function as a hard mask.

Thereafter, the second resist pattern 36 shown in FIGS. 9A to 9C is removed as shown in FIGS. 10A to 10C.

The processes shown in FIGS. 7A through 10C correspond to the hard mask layer forming process.

Subsequently, processes shown in FIGS. 11A to 11C are performed, which include the following processes. Portions of the second insulating film 19 and the first conductive film 32 shown through the plurality of openings 39, which are shown in FIGS. 10A to 10C, are removed using an anisotropic etching process (e.g., a dry etching process). Thereby, the electrode 18 is formed in a portion of the first groove 16 covered with the hard mask layer 33. In addition, portions of the silicon oxide film 15 shown through the plurality of openings 39 are removed. In other words, the first interlayer insulating film 13 is etched. Thereby, a plurality of second grooves 17 are formed. The plurality of second grooves 17 extend in the Y direction and intersect with the first grooves 16. These processes are referred to as an electrode and second groove forming process.

The second anti-reflection film 34 formed on the hard mask layer 33 is removed during the etching of the second insulating film 19 and the silicon oxide film 15.

When a TiN film is used as the first conductive film 32, the first conductive film 32 is dry etched using a mixture of Cl₂ gas (supplied at a flow rate of, for example, 50 sccm), CF₄ gas (supplied at a flow rate of, for example, 100 sccm), and Ar gas (supplied at a flow rate of, for example, 40 sccm) as an etching gas under a pressure of 10 mTorr at an inductively-coupled-plasma (ICP) power of 800 W and an RF bias power of 80 W.

In the electrode and second-groove forming process, a plurality of electrodes 18 having a U shape are formed. Each of the electrodes 18 includes a first conductive portion 23, a second conductive portion 24, and a third conductive portion 25. The first conductive portion 23 is disposed on a first side surface 16a of the first groove 16. The first conductive portion 23 has a top surface 23a shown on the surfaces of the first insulating film 11 and the silicon oxide film 15. The second conductive portion 24 is disposed on the second side surface 16b of the first groove 16. The second conductive portion 24 is shown on the surfaces of the first insulating film 11 and the silicon oxide film 15. The third conductive portion 25 is disposed on a portion of the bottom surface 16c of the first groove 16. The portion of the bottom surface 16c is disposed between the first conductive portion 23 and the second conductive portion 24.

Thus, portions of the first conductive film 32 formed on the first side surface 16a, the second side surface 16b, and bottom surface 16c of the first groove 16 are patterned by an anisotropic etching process using the hard mask layer 33 having the plurality of openings 39. The plurality of electrodes 18 are formed using the first conductive film 32 in the first grooves 16. As a result, downscaled electrodes 18 having a desired shape can be easily formed. Deviation in the shapes of the plurality of electrodes 18 can be suppressed.

In addition, since the plurality of electrodes 18 have a U shape, the areas of the top surfaces 23a and 24a of the first and second conductive portions 23 and 24 can be reduced with respect to cylindrical electrodes of the related art.

A process shown in FIGS. 12A to 12D is performed, which includes removing the hard mask layer 33 shown in FIGS. 11A to 11C (hard mask removing process).

When an amorphous carbon film is used as the hard mask layer 33, the hard mask layer 33 is removed by an ashing process using O₂ gas.

A process shown in FIGS. 13A to 13D is performed, which includes filling the plurality of second grooves 17 with a third insulating film 21 (third insulating film filling process). Thus, a structure 5 including an electrode structure 10 is fabricated.

In the third insulating film filling process, the third insulating film 21 is formed such that a top surface 21a of the third insulating film 21 is aligned in level to the top surface 15a of the silicon oxide film 15, the top surface 19a of the second insulating film 19, and the top surfaces 23a and 24a of the first and second conductive portions 23 and 24.

Specifically, the third insulating film 21 is formed as follows. The plurality of second grooves 17 are filled with, for example, a silicon oxide film or a silicon nitride film. Then, a protruding portion of the silicon oxide film or the silicon nitride film from the top surface 15a of the silicon oxide film 15 is removed. The portion of the silicon oxide film or the silicon nitride film protruding from the top surface 15a of the silicon oxide film 15 may be removed using, for example, an etch-back process or a CMP process.

When a silicon oxide film is employed as the third insulating film 21, the third insulating film 21 may be formed using, for example, a spinner process or an ALD process.

Thus, the plurality of second grooves 17 are filled with the coating-based third insulating film 21 using a spinner process to obtain a good gap filling property of the coating-based third insulating film 21. Thereby, generation of voids in the third insulating film 21 may be suppressed.

In addition, when a silicon nitride film is employed as the third insulating film 21, the third insulating film 21 may be formed using, for example, an LPCVD process.

In the method of fabricating the electrode structure according to the present embodiment, the first conductive film 32 serving as a base material of the electrode 18 is formed in the first grooves 16 extending in the Y direction instead of holes which is used as the related art. The first conductive film 32 can be formed to a uniform thickness on the first side surface 16a, the second side surface 16b, and the bottom surface 16c of each of the first grooves 16.

As a result, even if the first grooves 16 have about the same width defined as a dimension in the X direction as the diameter of the holes which is used as the related art, the formation process of the first conductive film 32 is not affected by the side surfaces of the first grooves 16 in the Y direction in which the first grooves 16 extend. Therefore, the first conductive film 32 can be easily formed in the first grooves 16.

In addition, portions of the first conductive film 32 which are shown through the plurality of openings 39 formed in the hard mask layer 33 are removed using an anisotropic etching process. The plurality of electrodes 18 formed of the first conductive film 32 are formed in the first grooves 16. Thus, the miniaturized electrodes 18 having a desired shape can be easily formed. A deviation between the shapes of the plurality of electrodes 18 can be suppressed.

In addition, since the plurality of electrodes 18 have a U shape, areas of the top surfaces 23a and 24a of the first and second conductive portions 23 and 24 can be reduced with respect to cylindrical electrodes of the related art.

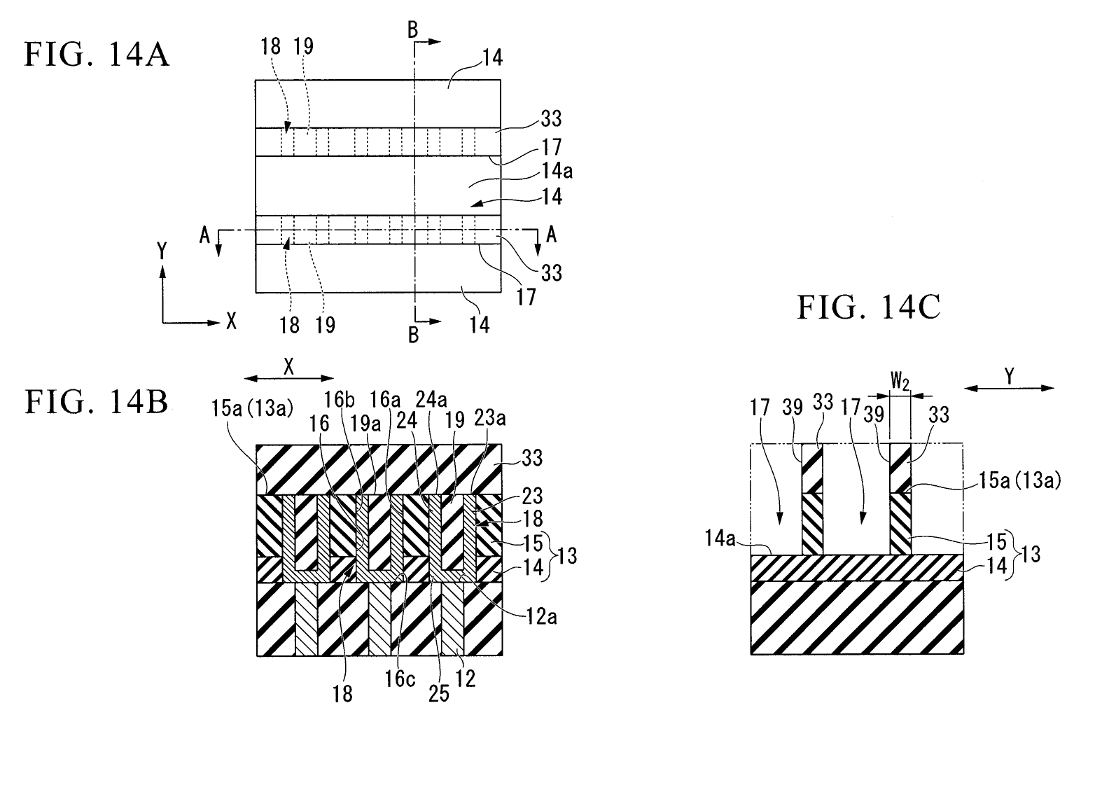

FIGS. 14A to 14C illustrates another process of fabricating the electrode structure according to the first embodiment of the present invention. FIG. 14A is a plan view of the electrode structure, FIG. 14B is a cross-sectional view taken along line A-A of FIG. 14A, and FIG. 14C is a cross-sectional view taken along line B-B of FIG. 14A.

Hereinafter, another method of fabricating the electrode structure 10 will be described with reference to FIGS. 14A to 14C.

As shown in FIGS. 14A to 14C, the plurality of second grooves 17 may be formed using an etching condition where side surfaces of the hard mask layer 33 corresponding to the openings 39 are side-etched. In the above-described process shown in FIGS. 11A to 11C (electrode and second groove forming process), the plurality of second grooves may be formed in this manner as shown in FIGS. 14A to 14C.

Thus, the plurality of second grooves 17 is formed using an etching condition where side surfaces of the hard mask layer 33 corresponding to the openings 39 are side-etched. The hard mask layer 33 with a width W₂ in Y-direction which is between the adjacent openings 39 is formed as shown in FIG. 14C. The width W₂ is smaller than a width W₁ in Y-direction of the hard mask layer 33 shown in FIG. 11C.

Thus, the electrodes 18 with a smaller width in Y-direction, that is, the width W₂ may be formed as shown in FIGS. 14A and 14B compared to the width W₁ in Y-direction of the electrodes 18 shown in FIGS. 11A and 11B. Hence, the size of the plurality of electrodes 18 in Y-direction may be easily miniaturized. In other words, the size in Y-direction of the plurality of electrodes 18 can be decreased less than the resolution limit of an exposure apparatus.

Thus, the top surfaces 23a and 24a of the first and second conductive portions 23 and 24 of the electrodes 18 shown in FIGS. 14A and 14B may have smaller areas than the top surfaces 23a and 24a of the first and second conductive portions 23 and 24 of the electrodes 18 shown in FIGS. 11A and 11B, respectively.

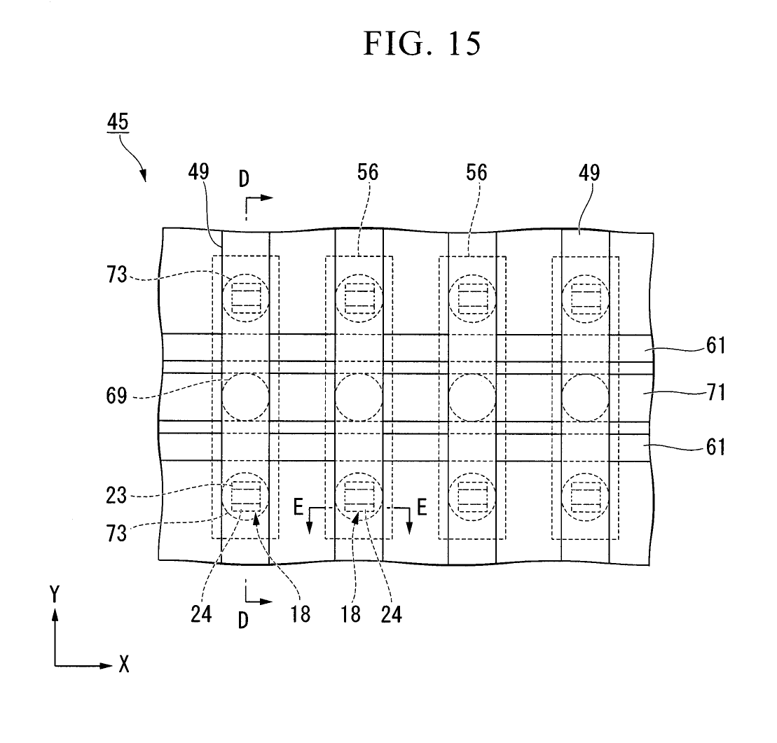

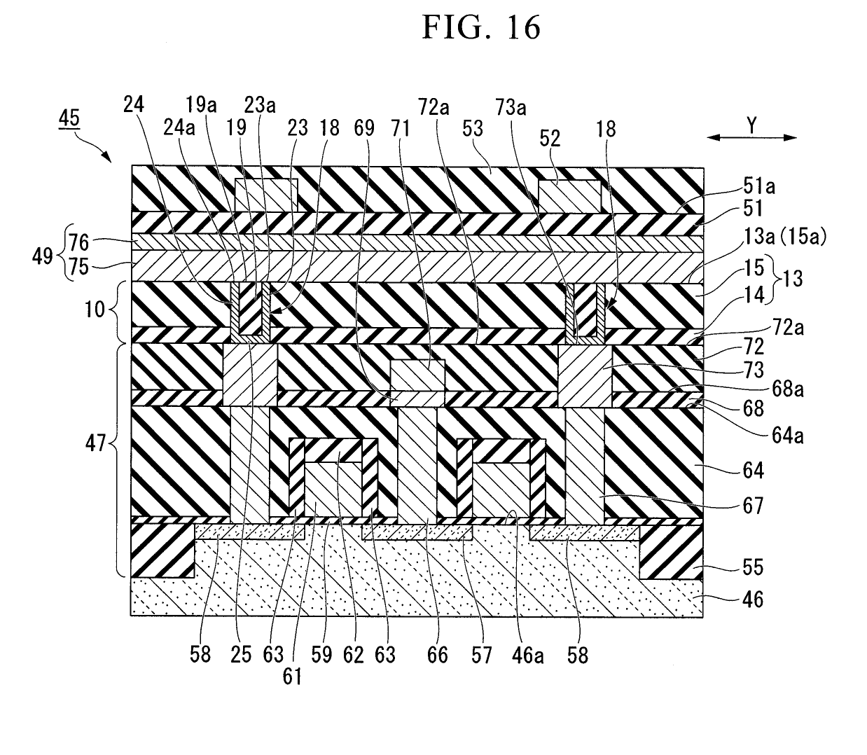

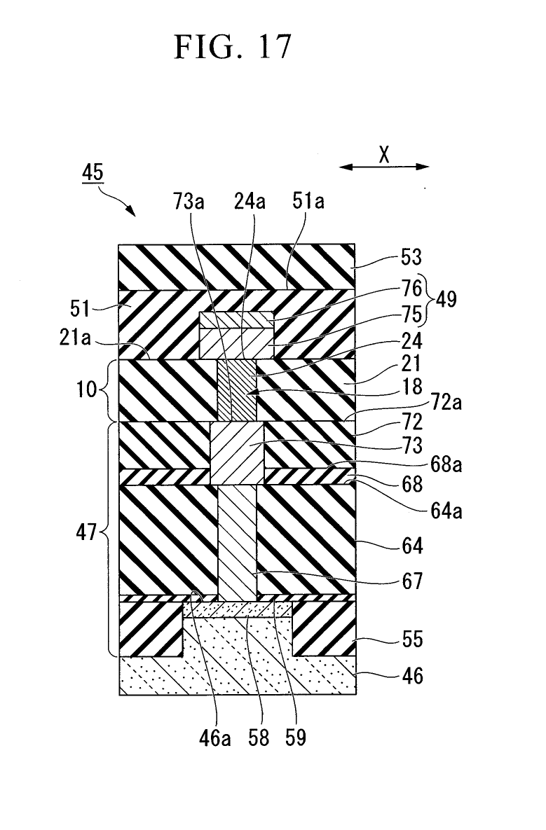

FIG. 15 is a schematic plan view illustrating a positional relationship among an active region, a gate electrode, a bit line, a ground interconnection, an electrode, a third contact plug, and a fourth contact plug formed in a semiconductor device including the electrode structure shown in FIGS. 1A to 1D. FIG. 16 is a fragmentary cross-sectional view taken along line D-D of the semiconductor device shown in FIG. 15, and FIG. 17 is a fragmentary cross-sectional view taken along line E-E of the semiconductor device shown in FIG. 15.

In addition, FIGS. 15 through 17 illustrate a phase-change memory (hereinafter, referred to as a PRAM) as an example of the semiconductor device. Also, since it is difficult to illustrate all components of a semiconductor device 45 shown in FIGS. 16 and 17 in FIG. 15, FIG. 15 illustrates some components of the semiconductor device 45.

An active region 56, a gate electrode 61, a bit line 49, a ground interconnection 71, an electrode 18, a third contact plug 69, and a fourth contact plug 73 are actually disposed on different planes in a direction of the thickness of the semiconductor device 45. However, FIG. 15 illustrates the active region 56, the gate electrode 61, the bit line 49, the ground interconnection 71, the electrode 18, the third contact plug 69, and the fourth contact plug 73 on the same plane.

In FIGS. 16 and 17, the same reference numerals are used to denote the same components as in the electrode structure of FIGS. 1A to 1D

As shown in FIGS. 15 through 17, the semiconductor device 45 includes an electrode structure 10, a semiconductor substrate 46, a multilayered interconnection structure 47, the bit line 49, a fifth interlayer insulating film 51, an interconnection 52, and a protection film 53.

The electrode structure 10 is formed over the multilayered interconnection structure 47. The electrode structure 10 is interposed between the multilayered interconnection structure 47 and the bit line 49. The electrode structure 10 is electrically connected to the multilayered interconnection structure 47 and the bit line 49.

The semiconductor substrate 46 may be a substrate having a first conductivity type (for example, a p type) for forming the multilayered interconnection structure 47. For example, a silicon substrate may be used as the semiconductor substrate 46.

The multilayered interconnection structure 47 includes an element isolation region 55, the active region 56, a first impurity diffusion region 57, a second impurity diffusion region 58, a gate insulating film 59, the gate electrode 61, a silicon nitride film 62, a sidewall film 63, a second interlayer insulating film 64, a first contact plug 66, a second contact plug 67, a third interlayer insulating film 68, the third contact plug 69, the ground interconnection 71, a fourth interlayer insulating film 72, and the fourth contact plug 73. A transistor may include, but is not limited to, the first impurity diffusion region 57, the second impurity diffusion region 58, the gate insulating film 59, and the gate electrode 61.

The element isolation region 55 may be formed in the semiconductor substrate 46. The element isolation region 55 may be formed using an insulating film, for example, a silicon oxide film. Shallow trench isolation (STI) may be employed to form the element isolation region 55.

The active region 56 may be a region partitioned by the element isolation region 55.

The first impurity diffusion region 57 may be formed in the semiconductor substrate 46 disposed between second impurity diffusion regions 58. The second impurity diffusion regions 58 may interpose the first impurity diffusion region 57 therebetween. The first and second impurity diffusion regions 57 and 58 may be regions in which impurities of a second conductivity type, for example, an N type, are diffused. One of the first and second impurity diffusion regions 57 and 58 functions as a source region. The other of the first and second impurity diffusion regions 57 and 58 functions as a drain region.

The gate insulating film 59 is formed on a surface 46a of the semiconductor substrate 46 and a top surface of the element isolation region 55. The surface 46a includes top surfaces of the first and second impurity diffusion regions 57 and 58.

The gate electrode 61 is formed on the gate insulating film 59 disposed between the first and second impurity diffusion regions 57 and 58. The gate electrode 61 extends in the X direction. The gate electrode 61 functions as a word line.

The silicon nitride film 62 is formed on the gate electrode 61. The silicon nitride film 62 is a film configured to protect the gate electrode 61.

The sidewall film 63 is formed to cover a side surface of the gate electrode 61. For example, a silicon nitride film may be used as the sidewall film 63.

The second interlayer insulating film 64 is formed over the gate insulating film 59 to cover the gate electrode 61, the silicon nitride film 62, and the sidewall film 63.

For example, a SiO₂ film may be used as the second interlayer insulating film 64.

The first contact plug 66 is formed to penetrate the second interlayer insulating film 64 over the first impurity diffusion region 57. Thus, a bottom of the first contact plug 66 is in contact with the first impurity diffusion region 57.

The second contact plug 67 is formed to penetrate the second interlayer insulating film 64 over the second impurity diffusion region 58. Thus, a bottom surface of the second contact plug 67 is in contact with the second impurity diffusion region 58.

The first and second contact plugs 66 and 67 may be formed of, for example, phosphorus (P)-containing polycrystalline silicon (poly-Si) or W.

A third interlayer insulating film 68 is formed on a top surface 64a of the second interlayer insulating film 64. For example, a silicon oxide film may be used as the third interlayer insulating film 68.

The third contact plug 69 is formed to penetrate the third interlayer insulating film 68 opposed to a top surface of the first contact plug 66. A bottom surface of the third contact plug 69 is in contact with the top surface of the first contact plug 66. Thus, the third contact plug 69 is electrically connected to the first impurity diffusion region 57 through the first contact plug 66. For example, W may be used as a material of the third contact plug 69.

As shown in FIG. 15, the ground interconnection 71 extends in the X direction. The ground interconnection 71 is in contact with a plurality of third contact plugs 69 disposed in the X direction. The ground interconnection 71 is configured to provide a ground electric potential level to a plurality of third contact plugs 69.

A fourth interlayer insulating film 72 is formed on a top surface 68a of the third interlayer insulating film 68 to cover the ground interconnection 71. The silicon nitride film 14 which is a part of the electrode structure 10 is formed on a top surface 72a of the fourth interlayer insulating film 72.

A fourth contact plug 73 is formed to penetrate the third and fourth interlayer insulating films 68 and 72 disposed over the second contact plug 67. A bottom surface of the fourth contact plug 73 is in contact with a top surface of the second contact plug 67. Thus, the fourth contact plug 73 is electrically connected to the second impurity diffusion region 58 through the second contact plug 67.

The fourth contact plug 73 is disposed so that a top surface 73a of the fourth contact plug 73 is aligned in level to the top surface 72a of the fourth interlayer insulating film 72.

The top surface 73a of the fourth contact plug 73 is connected to the third conductive portion 25 which is a part of the electrode structure 10. Thus, the electrode 18 is electrically connected to the second impurity diffusion region 58 through the second and fourth contact plugs 67 and 73. For example, W may be used as a material of the fourth contact plug 73.

The bit line 49 includes a variable resistance material layer 75 and an interconnection 76 stacked sequentially. The variable resistance material layer 75 is formed on the top surface 15a of the silicon oxide film 15, the top surface 19a of the second insulating film 19, and a portion of the top surface 21a of the third insulating film 21. The variable resistance material layer 75 extends in the Y direction.

The variable resistance material layer 75 is in contact with top surfaces of the plurality of electrodes 18 arranged in the Y direction. Specifically, the variable resistance material layer 75 is in contact with the top surfaces 23a and 24a of the first and second conductive portions 23 and 24.

As described above, the U-shaped electrode 18 having the first through third conductive portions 23, 24, and 25 is formed. The variable resistance material layer 75 is in contact with the top surfaces 23a and 24a of the first and second conductive portions 23 and 24. Thus, a contact area between the electrode 18 and the variable resistance material layer 75 is smaller than another contact area between the cylindrical electrode of the related art and a variable resistance material layer. The variable resistance material layer 75 is heated by the electrode 18.

As a result, it is possible to reduce a region where the resistance of the variable resistance material layer 75 is changed. Specifically, as one example of the variable resistance material layer 75, the phase change material layer is given. The phase change material is transitioned from a high-resistance amorphous state into a low-resistance crystalline state or transitioned from the crystalline state into the amorphous state. Thereby, data may be written or read at high speed.

As described above, the phase change material may be used as a material of the variable resistance material layer 75. A chalcogenide material may be used as the phase change material. The chalcogenide material may be an alloy containing at least one element selected from the group consisting of germanium (Ge), antimony (Sb), tellurium (Te), indium (In), and selenium (Se).

Specifically, the chalcogenide material may be, for example, a binary element such as GaSb, InSb, InSe, Sb₂Te₃, or GeTe, a ternary element such as Ge₂Sb₂Te₅, InSbTe, GaSeTe (GST), SnSb₂Te₄, or InSbGe, or a quaternary element such as AgInSbTe, (GeSn)SbTe, GeSb(SeTe), or Te₈₁Ge₁₅Sb₂S₂.

The interconnection 76 is formed on the variable resistance material layer 75. The interconnection 76 extends in the Y direction. For example, a Ti film, a TiN film, or a Ti/TiN stack film may be used as the interconnection 76.

A fifth interlayer insulating film 51 is formed on the top surface 21a of the third insulating film 21 to cover the bit line 49. The fifth interlayer insulating film 51 may be, for example, a SiO₂ film.

The interconnection 52 is formed on a top surface 51a of the fifth interlayer insulating film 51. The interconnection 52 is electrically connected to the multilayered interconnection structure 47. The interconnection 52 has an electrode pad unit (not shown) serving as an external connection pad. The interconnection 52 may be formed of, for example, aluminum (Al) or copper (Cu).

According to the semiconductor device of the present embodiment, a contact area between the U-shaped electrode 18 (the electrode 18 having the concave portion) and the variable resistance material layer 75 can be reduced. Here, the U-shaped electrode 18 includes the top surfaces 23a and 24a of the first and second conductive portions 23 and 24. The top surfaces 23a and 24a is in contact with the variable resistance material layer 75 for heating the variable resistance material layer 75.

Thus, it is possible to reduce a region where the resistance of the variable resistance material layer 75 is changed. Specifically, the variable resistance material layer 75 is transitioned from a high-resistance amorphous state into a low-resistance crystalline state or transitioned from the crystalline state into the amorphous state. Thereby, data may be written or read at high speed.

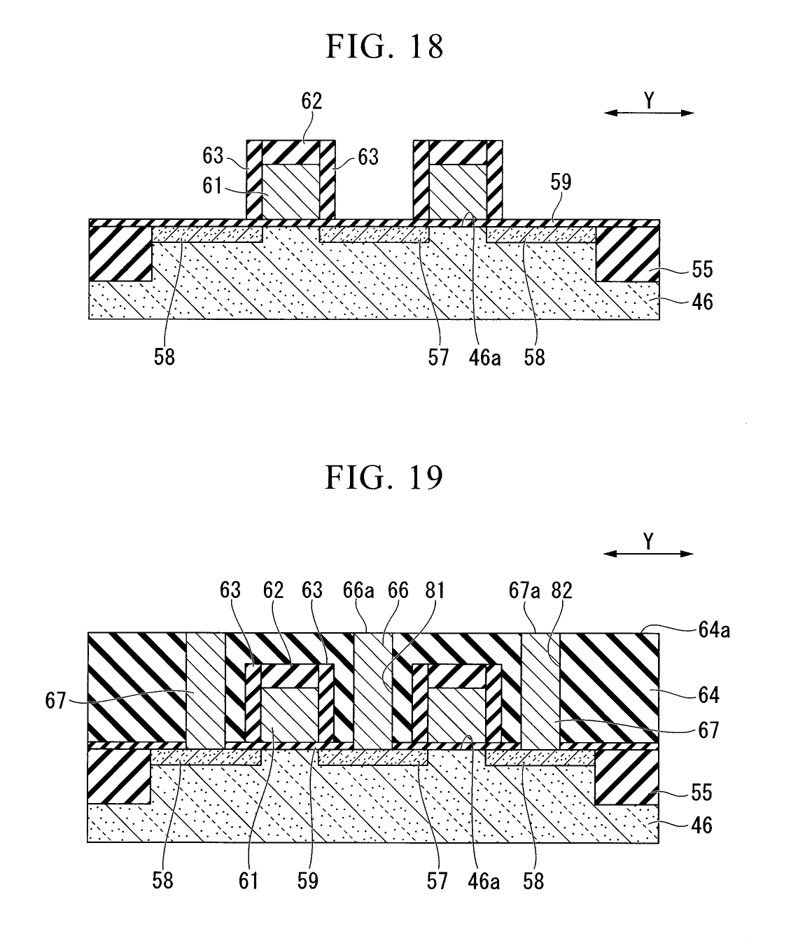

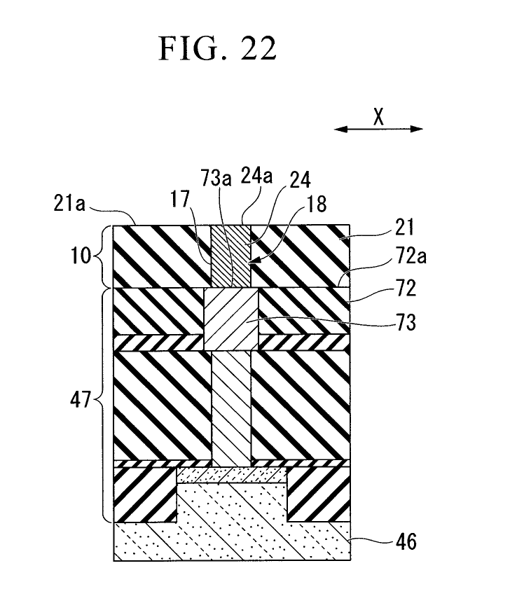

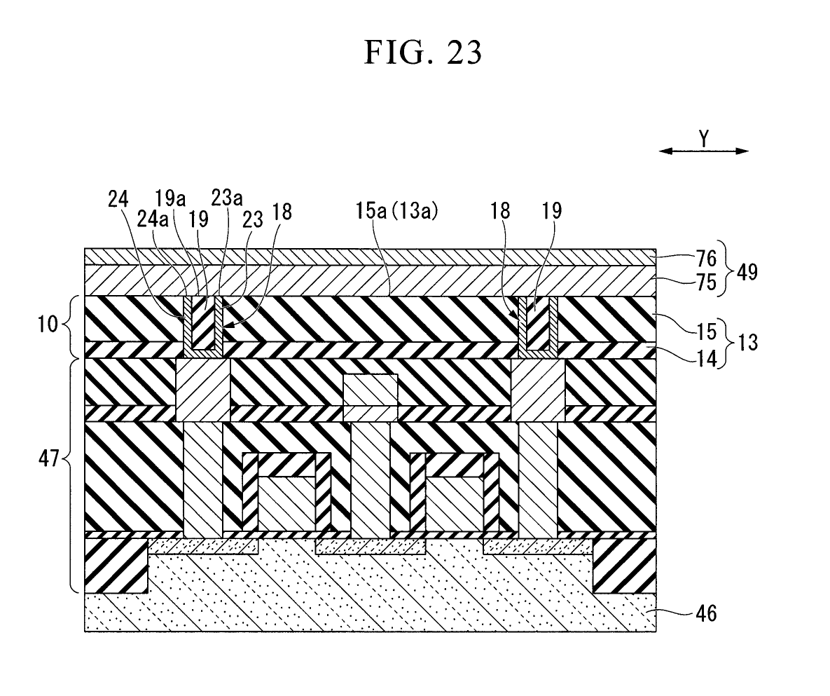

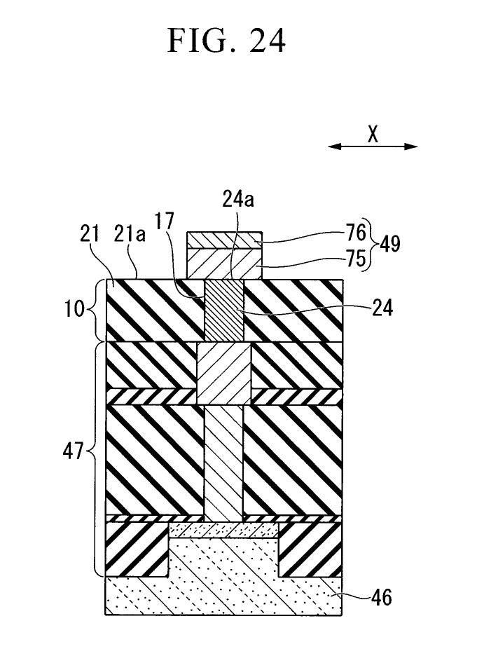

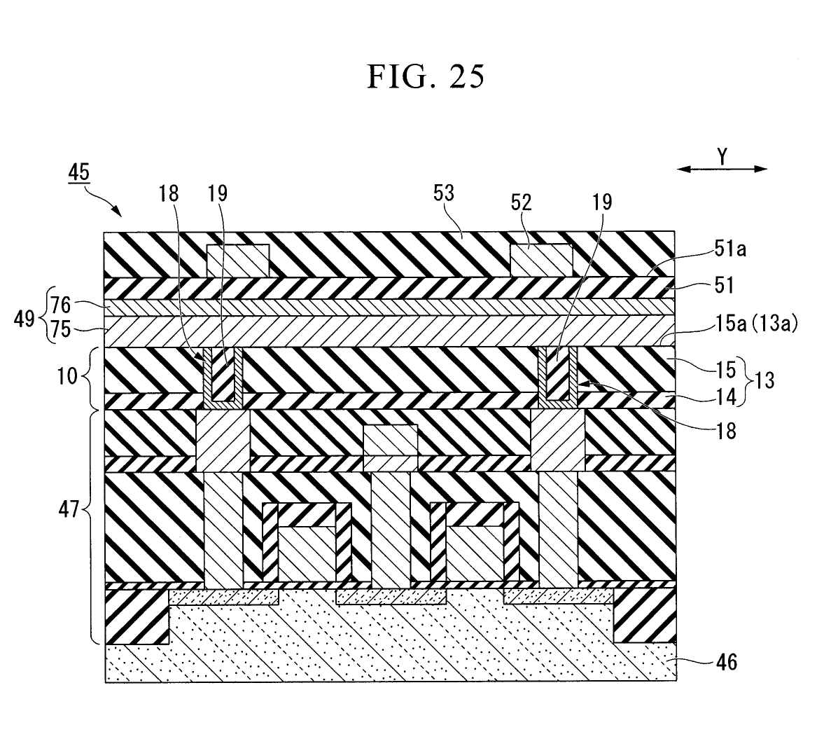

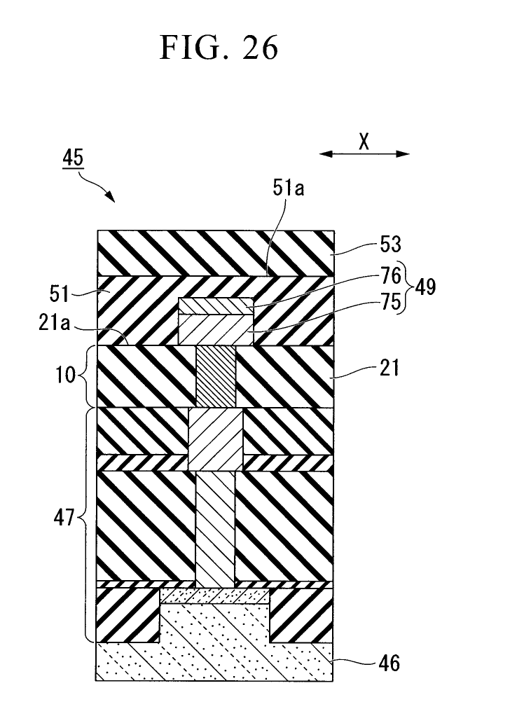

FIGS. 18 through 21, 23, and 25 are fragmentary cross-sectional views illustrating a process of fabricating a semiconductor device including the electrode structure shown in FIGS. 1A to 1D. FIG. 22 is a fragmentary cross-sectional view of the structure of FIG. 21 corresponding to a cross-sectional view of the semiconductor device 45 taken along line E-E of FIG. 15. FIG. 24 is a fragmentary cross-sectional view of the structure of FIG. 23 corresponding to the cross-sectional view of the semiconductor device 45 taken along line E-E of FIG. 15. FIG. 26 is a fragmentary cross-sectional view of the structure of FIG. 25 corresponding to the cross-sectional view of the semiconductor device 45 taken along line E-E of FIG. 15.

In addition, FIGS. 18 through 21, 23, and 25 correspond to a cross-sectional view of the semiconductor device 45 taken along line D-D of FIG. 15. In other words, FIGS. 18 through 21, 23, and 25 correspond to the semiconductor device 45 shown in FIG. 16. Also, in FIGS. 18 through 26, the same reference numerals are used to denote the same components as in the semiconductor device 45 of FIG. 16.

A method of fabricating the semiconductor device 45 including the electrode structure 10 shown in FIGS. 1A to 1D will now be described with reference to FIGS. 18 through 26.

As shown in FIG. 18, an element isolation region 55, for example, an STI region, is formed in a semiconductor substrate 46 of a first conductivity type (for example, a p type). Thereafter, a gate insulating film 59 is formed on a surface 46a of the semiconductor substrate 46 and the element isolation region 55. For example, a silicon oxide film may be used as the gate insulating film 59. Afterwards, a gate electrode 61 and a silicon nitride film 62 are sequentially formed on the gate insulating film 59 using a known method. Thereafter, impurities of a second conductivity type (for example, n-type impurities such as P) are implanted into the semiconductor substrate 46. Thereby, first and second impurity diffusion regions 57 and 58 are formed. Subsequently, a sidewall film 63 is formed to cover a side surface of the gate electrode 61 using a known method.

In addition, although not shown in FIG. 18, after forming the sidewall film 63, the impurities of the second conductivity type may be heavily implanted into the semiconductor substrate 46 to form a lightly-doped-drain (LDD)-type transistor.

Thereafter, a process shown in FIG. 19 is performed, which includes forming a second interlayer insulating film 64 to cover the silicon nitride film 62 and the sidewall film 63. The second interlayer insulating film 64 may be, for example, a silicon oxide film.

Thereafter, through holes 81 and 82 are formed through the second interlayer insulating film 64 and the gate insulating film 59. The first impurity diffusion region 57 is shown through the through hole 81. The second impurity diffusion region 58 is shown through the through hole 82.

Thereafter, a first contact plug 66 is formed in the through hole 81. A second contact plug 67 is formed in the through hole 82. Top surfaces 66a and 67a of the first and second contact plugs 66 and 67 are aligned in level to a top surface 64a of the second interlayer insulating film 64.

The first and second contact plugs 66 and 67 are formed by filling the through holes 81 and 82 with, for example, P-type impurity containing poly-Si or W.

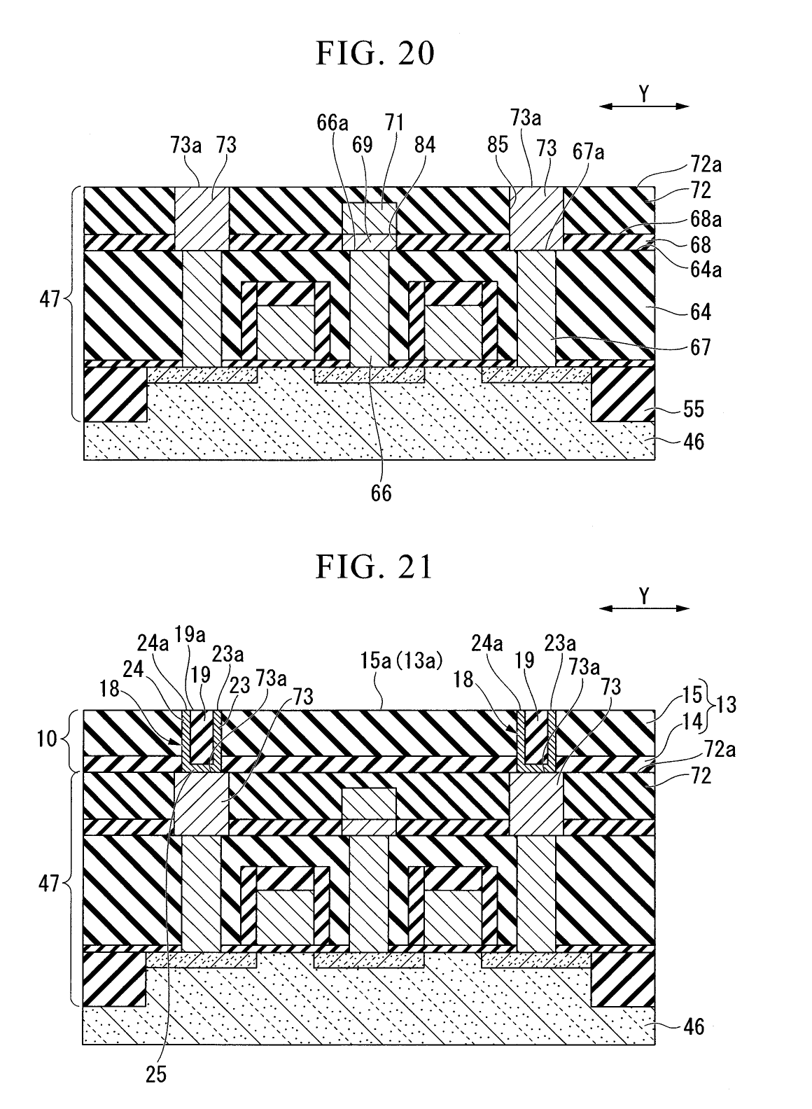

A third interlayer insulating film 68 is formed on the top surface 64a of the second interlayer insulating film 64 as shown in FIG. 20. The third interlayer insulating film 68 has a through hole 84 reaching a top surface 66a of the first contact plug 66. For example, a silicon oxide film may be used as the third interlayer insulating film 68. Subsequently, a third contact plug 69 is formed in the through hole 84. The third contact plug 69 may be formed of, for example, W.

Thereafter, a ground interconnection 71 contacting a top surface of the third contact plug 69 is formed on a top surface 68a of the third interlayer insulating film 68.

Thereafter, a fourth interlayer insulating film 72 is formed on the top surface 68a of the third interlayer insulating film 68 to cover the ground interconnection 71. The fourth interlayer insulating film 72 may be, for example, a silicon oxide film.

Thereafter, a through hole 85 is formed in the third and fourth interlayer insulating films 68 and 72. The top surface 67a of the second contact plug 67 is shown through the through hole 85.

Thereafter, a fourth contact plug 73 is formed to fill the through hole 85.

A top surface 73a of the fourth contact plug 73 is aligned in level to a top surface 72a of the fourth interlayer insulating film 72. The fourth contact plug 73 may be formed of, for example, W.

Thus, a multilayered interconnection structure 47 is formed on the semiconductor substrate 46.

Thereafter, a process shown in FIG. 21 is performed, which includes forming an electrode structure 10 on the top surface 72a of the fourth interlayer insulating film 72 and the top surface 73a of the fourth contact plug 73 (a top surface of the multilayered interconnection structure 47) using a similar process to the above-described process shown in FIGS. 2 through 13.

In this case, the electrode structure 10 is formed such that the third conductive portion 25 of the electrode 18 is in contact with the top surface 73a of the fourth contact plug 73. Thus, the multilayered interconnection structure 47 is electrically connected to the electrode structure 10.

A process shown in FIG. 21 includes filling a second groove 17 with a third insulating film 21 as shown in FIG. 22.

Thereafter, as shown in FIGS. 23 and 24, the variable resistance material layer 75 and the interconnection 76 are sequentially stacked on the top surface 15a of the silicon oxide film 15 (a top surface 13a of a first interlayer insulating film 13) and the top surface 21a of the third insulating film 21. The variable resistance material layer 75 is in contact with top surfaces 23a and 24a of the first and second conductive portions 23 and 24 and the top surface 19a of the second insulating film 19. The first and second conductive portions 23 and 24 are formed of the plurality of electrodes 18 disposed in the Y direction. The interconnection 76 is formed over the variable resistance material layer 75. The variable resistance material layer 75 and the interconnection 76 form a bit line 49.

Thus, the U-shaped electrode 18 having the first through third conductive portions 23 to 25 is formed. The variable resistance material layer 75 is in contact with the top surfaces 23a and 24a of the first and second conductive portions 23 and 24. Thus, a contact area between the electrode 18 for heating the variable resistance material layer 75 and the variable resistance material layer 75 is smaller than a contact area between the cylindrical electrode of the related art and a variable resistance material layer.

Thus, it is possible to reduce a region where the resistance of the variable resistance material layer 75 is changed. Specifically, the variable resistance material layer 75 is transitioned from a high-resistance amorphous state into a low-resistance crystalline state or transitioned from the crystalline state into the amorphous state. Thereby, the semiconductor device is included in high speed performance to read and write data at high speed.

As shown in FIGS. 25 and 26, a fifth interlayer insulating film 51 is formed on the top surface 15a of the silicon oxide film 15 (the top surface 13a of the first interlayer insulating film 13) and the top surface 21a of the third insulating film 21 to cover the bit line 49. The silicon oxide film 15 and the third insulating film 21 are formed in the structure shown in FIGS. 23 and 24. Then, an interconnection 52 is formed on the top surface 51a of the fifth interlayer insulating film 51. A protection film 53 is formed on the top surface 51a of the fifth interlayer insulating film 51 to cover the interconnection 52. Thus, the semiconductor device 45 according to the present embodiment is fabricated.

### Second Embodiment

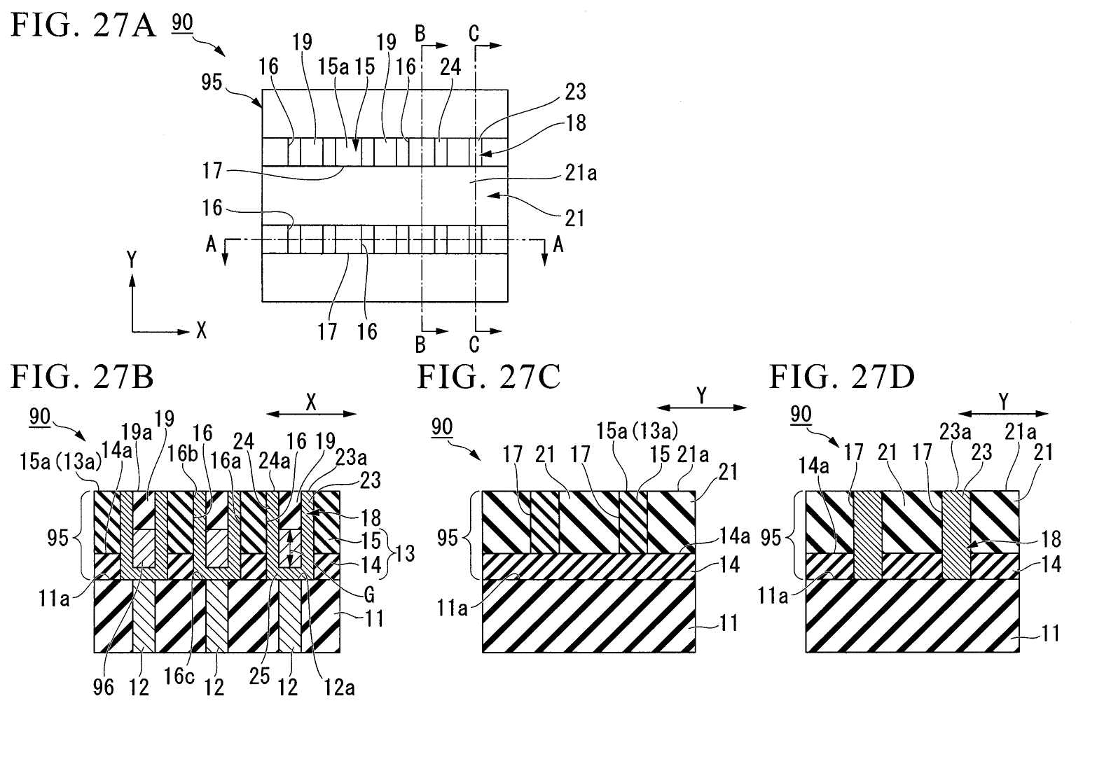

FIGS. 27A to 27D are fragmentary schematic views illustrating a structure including an electrode structure according to a second embodiment of the present invention. FIG. 27A is a fragmentary plan view of the structure, FIG. 27B is a fragmentary cross-sectional view taken along line A-A of FIG. 27A, FIG. 27C is a fragmentary cross-sectional view taken along line B-B of FIG. 27A, and FIG. 27D is a fragmentary cross-sectional view taken along line C-C of FIG. 27A.

Also, in FIGS. 27A to 27D, the same reference numerals are used to denote the same components as in the structure 5 of FIGS. 1A to 1D according to the first embodiment.

Referring to FIGS. 27A to 27D, a structure 90 according to the second embodiment has a similar structure to the structure 5 except that an electrode structure 95 is formed instead of the electrode structure 10 formed in the structure 5 according to the first embodiment.

The electrode structure 95 has a similar structure to the electrode structure 10 except that a second conductive film 96 is further formed.

The second conductive films 96 are formed in portions of a plurality of first grooves 16 interposed between the second insulating film 19 and the third conductive portion 25. The second conductive film 96 may be formed of, for example, W.

According to the electrode structure of the present embodiment, the second conductive films 96 are formed in the portions of the plurality of first grooves 16 interposed between the second insulating film 19 and the third conductive portion 25. Hence, the resistance of the electrode 18 can be lowered.

In addition, the second conductive films 96 fill the portions of the plurality of first grooves 16 interposed between the second insulating film 19 and the third conductive portion 25. A thickness G of the second conductive films 96 is determined such that the electrode 18 filled with the second conductive film 96 has a desired resistance.

FIGS. 28 through 30 are diagrams illustrating a process of fabricating an electrode structure according to a second embodiment of the present invention. FIGS. 28 through 30 are fragmentary cross-sectional views corresponding to a cross-sectional view of the structure 90 taken along line A-A of FIG. 27A. In FIGS. 28 through 30, the same reference numerals are used to denote the same components as in the structure 90 shown in FIGS. 27A to 27D.

A method of fabricating the electrode structure 95 according to the second embodiment will now be described with reference to FIGS. 28 through 30.

A similar process to the process described in the first embodiment with reference to FIGS. 2A through 5C is performed, thereby forming the structure shown in FIGS. 5A to 5C. Thereafter, the first conductive film forming process described in the first embodiment with reference to FIGS. 6A to 6C is performed. Thereby, first conductive film 32 in a plurality of first grooves 16 (first conductive film forming process) is formed. As will be described later with reference to FIG. 28, the first conductive film 32 is formed on a top surface 15a of a silicon oxide film 15 also. That is, during the current step, the first conductive film 32 is formed not only in the plurality of first grooves 16 but also over other portions.

As shown in FIG. 28, the plurality of first grooves 16 are filled with a second conductive film 96. Etching back the second conductive film 96 is performed to a whole surface. Thereby, the second conductive films 96 with a thickness G are formed in the plurality of first grooves 16 (second conductive film filling process).

The second conductive film 96 may be formed of a different material from the first conductive film 32.

By forming the second conductive film 96 using a different material from the first conductive film 32, when etching back the second conductive film 96, the first conductive film 32 formed in the first grooves 16 may be prevented to be etched. In other words, the second conductive film 96 may be selectively etched.

When a TiN film is used as the first conductive film 32, the second conductive film 96 may be formed of, for example, W.

In the second conductive film filling process, the second conductive film 96 is filled to a smaller depth than the first grooves 16 in which the first conductive film 32 is formed.

As shown in FIG. 29, the plurality of first grooves 16 in which the second conductive film 96 is formed is filled with a second insulating film 19 (second insulating film filling process).

The second insulating film 19 is formed using a similar process to the process described in the first embodiment with reference to FIGS. 6A to 6C. As shown in FIG. 29, the second insulating film 19 is formed on the first conductive film 32 also.

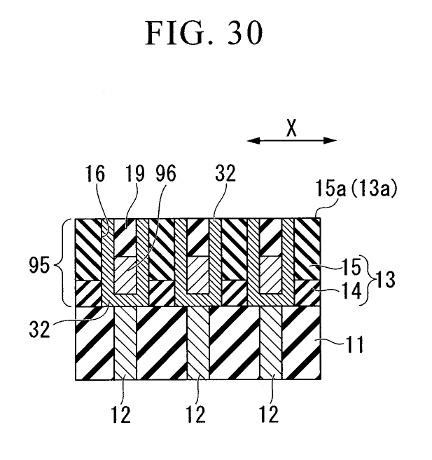

As shown in FIG. 30, portions of the first conductive film 32 and the second insulating film 19 above the top surface 15a of the silicon oxide film 15 (a top surface 13a of a first interlayer insulating film 13) shown in FIG. 29 are removed (first conductive film and second insulating film removing process).

Afterwards, a similar process to the process described in the first embodiment with reference to FIGS. 7A through 10C is performed. Thereafter, in the process described in the first embodiment with reference to FIGS. 11A to 11C (i.e., the electrode and second groove forming process), portions of the second insulating film 19, the first conductive film 32, and the second conductive film 96 (not shown) shown through the plurality of openings 39 are removed using an anisotropic etching process (for example, a dry etching process). Thus, an electrode 18 having the second conductive film 96 is formed in a portion of the first groove 16 covered with a hard mask layer 33. Also, portions of the silicon oxide film 15 shown through the plurality of openings 39 are removed. That is, a portion of the first interlayer insulating film 13 is etched. Thereby, a plurality of second grooves 17 are formed. The plurality of second grooves 17 extend in the Y direction and intersect with the first grooves 16.

Afterwards, the process described in the first embodiment with reference to FIGS. 12A to 13D is performed, thereby fabricating the electrode structure 95 of FIGS. 27A to 27D according to the present embodiment.

In the method of fabricating the electrode structure according to the present embodiment, between the first conductive film forming process and the second insulating film filling process, the second conductive film 96 with a smaller depth is formed with respect to a depth of the first groove 16 in which the first conductive film 32 is formed (second conductive film filling process). Hence, the resistance of the electrode 18 is reduced.

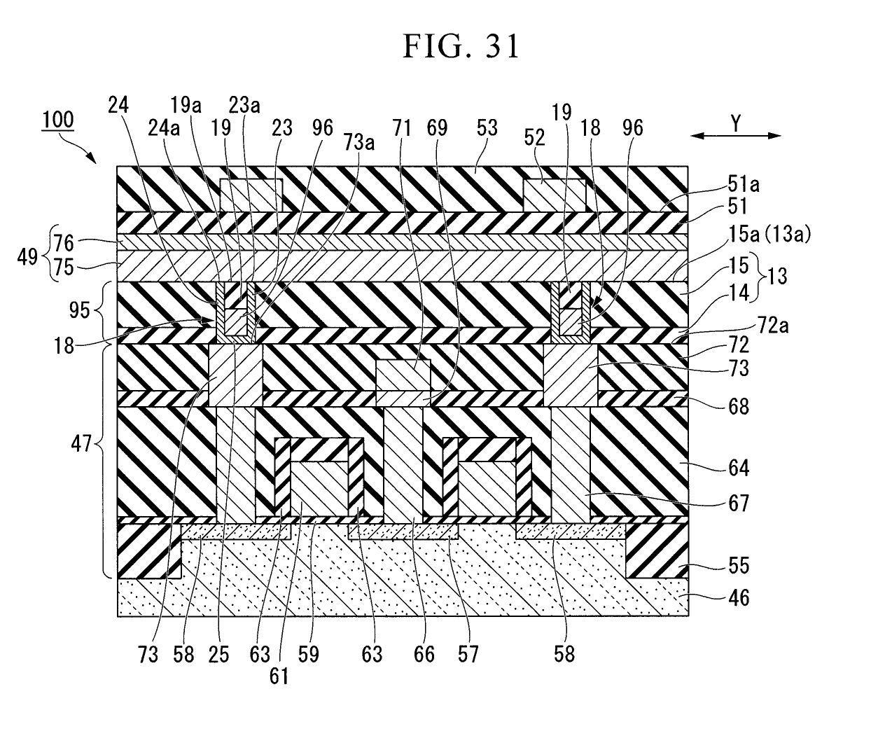

FIG. 31 is a fragmentary cross-sectional view of a semiconductor device including the electrode structure shown in FIGS. 27A to 27D. Also, FIG. 31 exemplarily illustrates a case where a PRAM is used as an example of a semiconductor device. Also, in FIG. 31, the same reference numerals are used to denote the same components as in the semiconductor device 45 of FIG. 16 according to the first embodiment and the electrode structure 95 of FIGS. 27A to 27D.

Referring to FIG. 31, a semiconductor device 100 according to the second embodiment has a similar structure to the semiconductor device 45 (refer to FIG. 16) of the first embodiment except that the electrode structure 95 of FIGS. 27A to 27D is used instead of the electrode structure 10 of the semiconductor device 45.

The electrode structure 95 is formed between a bit line 49 and a multilayered interconnection structure 47. Thus, the electrode structure 95 is electrically connected to the bit line 49 and the multilayered interconnection structure 47. The electrode structure 95 is formed over the multilayered interconnection structure 47. A third conductive portion 25 of an electrode 18 is in contact with a top surface 73a of a fourth contact plug 73. Also, top surfaces 23a and 24a of first and second conductive portions 23 and 24 of the electrode 18 are in contact with a variable resistance material layer 75.

The semiconductor device 100 having the above-described structure may be fabricated using a similar method to the methods of fabricating the semiconductor device 45 of the first embodiment described with reference to FIGS. 28 through 30 except that the electrode structure 95 is formed.

While the invention has been particularly shown and described with reference to specific and exemplary embodiments thereof, it will be understood that the scope of the invention is not limited to the specific embodiments and various changes and modifications in form and details may be made therein without departing from the spirit and scope of the following claims.

For example, while the first and second embodiments illustrate that PRAMs are used as examples of the semiconductor devices 45 and 100, the electrode structures 10 and 95 described in the first and second embodiments may be formed in semiconductor devices other than the PRAMs.

The above described embodiments may be modified as follows. The semiconductor device may include, but is not limited to, a phase change layer and an electrode. The electrode generates a heat upon application of current. The heat will be conducted to the phase change layer. The heat will transition between crystalline and amorphous states of the phase change layer. Typically, the electrode may be disposed in contact with the phase change layer. In other cases, the electrode may be disposed so close to the phase change layer that the heat generated by the electrode will be conducted to the phase change layer and the heat will cause phase transitions between crystalline and amorphous states of the phase change layer. Generally, the electrode may be disposed and thermally coupled with the phase change layer so that the heat generated by the electrode will be conducted to the phase change layer and the heat will cause phase transitions between crystalline and amorphous states of the phase change layer. In modified cases, the electrode may not be contact directly with the phase change layer but is thermally coupled with the phase change layer. The electrode includes an adjacent portion which is adjacent to the phase change layer. The heat will be conducted through the adjacent portion to the phase change layer. In some cases, the electrode may be disposed in a hole of a layered structure adjacent to the phase change layer. The electrode may be a part of the structure in the hole. The structure may include the electrode and a non-electrode. Generally, the structure may include, but is not limited to, an adjacent portion including a conductive portion and a non-conductive portion. The conductive portion performs as the adjacent portion of the electrode. This structure is smaller in heat conductance area than the known electrode filling the hole. The structure with the reduced heat conductance area reduces a phase change area of the phase change layer. The reduced phase change area can improve high speed performance of the semiconductor device which utilizes phase transitions between crystalline and amorphous states of the phase change layer.

In other cases, the above structure may include a first portion and a second portion. The heat will be conducted through the first portion to the phase change layer. The first portion is thermally coupled with the phase change layer to allow heat conduction through the first portion to the phase change layer. The second portion is electrically coupled with a conductor connected to another element. The first portion is smaller in horizontal dimension than the second portion. In some cases, the first portion may be in contact with the phase change layer and the second portion may be in contact with the conductor. The first portion is smaller in contact area than the second portion. In some cases, the electrode may be disposed in the hole of the layered structure adjacent to the phase change layer. The electrode may be a part of the structure in the hole. The structure may include the electrode and the non-electrode. The structure is smaller in heat conductance area than the known electrode filling the hole. The structure with the reduced heat conductance area reduces the phase change area of the phase change layer. The reduced phase change area can improve high speed performance of the semiconductor device which utilizes phase transitions between crystalline and amorphous states of the phase change layer.

The embodiments of the present invention are applicable to an electrode structure including an electrode, a method of fabricating the same, and a semiconductor device including the electrode structure.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method for fabricating a semiconductor device, the method comprising:
forming a first groove in a first insulating film;
forming a first conductive film on inner surfaces of the first groove; and
forming a second groove in the first insulating film to remove a part of the first conductive film, the second groove intersecting the first groove.

2. The method according to claim 1, further comprising:
forming a second insulating film on the first conductive film, the second insulating film being in the first groove,
wherein forming the second groove comprises removing a part of the first conductive film and a part of the second insulating film.

3. The method according to claim 1, further comprising:
forming a second conductive film in contact with the first conductive film, the second conductive film being in the first groove.

4. The method according to claim 3, further comprising:
forming a second insulating film on the first conductive film and the second conductive film, the second insulating film being in the first groove,
wherein forming the second groove comprises selectively removing the first conductive film, the second conductive film, and the second insulating film.

5. The method according to claim 1, wherein forming the second groove comprises:
forming a mask over the first conductive film; and
selectively removing the first insulating film and the first conductive film using the mask.

6. The method according to claim 3, wherein forming the second groove comprises:
forming a mask over the first conductive film; and
selectively removing the first insulating film, the first conductive film, and the second conductive film using the mask.

7. The method according to claim 4, wherein forming the second groove comprises:
forming a mask over the first conductive film; and
selectively removing the first insulating film, the first conductive film, the second conductive film, and the second insulating film using the mask.

8. The method according to claim 5, wherein forming the mask comprises:
reducing a width of the mask.

9. The method according to claim 5, wherein forming the mask comprises:
forming a hard mask over the first conductive film;
forming an anti-reflection film over the hard mask; and
forming a resist pattern over the anti-reflection film.

10. The method according to claim 1, further comprising:
forming a variable resistance material layer in contact with a top surface of the first conductive film.

11. A method for fabricating a semiconductor device, the method comprising:
forming a first groove in a first insulating film;
forming a first conductive film on inner surfaces of the first groove; and
forming second and third grooves in the first insulating film to define the first conductive film into an electrode, the second and third grooves intersecting the first groove.

12. The method according to claim 11, further comprising:
forming a second insulating film on the first conductive film, the second insulating film being in the first groove,
wherein forming the second and third grooves comprises selectively removing the first conductive film and the second insulating film.

13. The method according to claim 11, further comprising:
forming a second conductive film in contact with the first conductive film, the second conductive film being in the first groove.

14. The method according to claim 13, further comprising:
forming a second insulating film on the first conductive film and the second conductive film, the second insulating film being in the first groove,
wherein forming the second and third grooves comprises selectively removing the first conductive film, the second conductive film, and the second insulating film.

15. The method according to claim 11, wherein forming the second and third grooves comprises:
forming a mask over the first conductive film; and
selectively removing the first insulating film and the first conductive film using the mask.

16. The method according to claim 15, wherein forming the mask comprises:
reducing a width of the mask.

17. The method according to claim 11, further comprising:
forming a variable resistance material layer in contact with a top surface of the first conductive film.

18. A method for fabricating a semiconductor device, the method comprising:
forming a first insulating film over a semiconductor substrate;
forming a first groove in the first insulating film, the first groove extending in a first direction;
forming a first conductive film on a bottom surface and side surfaces of the first groove; and
forming a second groove in the first insulating film to remove a part of the first conductive film and to define an electrode, the second groove extending in a second direction, the second groove intersecting the first groove.

19. The method according to claim 18, further comprising:
forming a second insulating film on the first conductive film, the second insulating film being in the first groove,
wherein forming the second groove comprises removing a part of the first conductive film and a part of the second insulating film.

20. The method according to claim 19, further comprising:
forming a variable resistance material layer in contact with a top surface of the first conductive film.
